(19) United States
(12) Patent Application Publication
(10) Pub. No.: US 2023/0004852 A1
(43) Pub. Date: Jan. 5, 2023

(54) CONVERSION METHOD, CONVERSION DEVICE, RECEPTION DEVICE, AND TRANSMISSION DEVICE

(71) Applicant: SONY GROUP CORPORATION, TOKYO (JP)

(72) Inventors: NAOKI IDE, TOKYO (JP); HIROSHI UENO, TOKYO (JP); TETSUYA ASAYAMA, TOKYO (JP)

(21) Appl. No.: 17/778,750

(22) PCT Filed: Oct. 21, 2020
(86) PCT No.: PCT/JP2020/039476

§ 371 Date: May 20, 2022

(30) Foreign Application Priority Data
Nov. 29, 2019 (JP) 2019-216872

(51) Int. Cl. G06N 10/60

(52) U.S. Cl. CPC G06N 10/60

(57) ABSTRACT

A conversion method according to the present disclosure, is a method of converting an objective function of combinatorial optimization related to encoding and decoding into a form of an Ising model, the conversion of the objective function into the form of the Ising model being performed by the conversion method, and the method includes: removing a modulo 2 operation from the objective function by using first transformation; replacing a first variable to be optimized included in the objective function with a second variable corresponding to an Ising spin by using second transformation; and reducing a degree related to the second variable of the objective function by using third transformation.

### FIELD

The present disclosure relates to a conversion method, a conversion device, a reception device, and a transmission device.

### BACKGROUND

There have been proposed various known coding techniques such as channel coding and source coding. An example of known channel coding is Low-Density Parity check Code (LDPC code; hereinafter referred to as LDPC) (for example, Patent Literature 1).

### CITATION LIST

### Non Patent Literature

Non Patent Literature 1: “Interior Point Decoding for Linear Vector Channels” Tadashi Wada Yama <Internet> https://arxiv.org/pdf/0705.3990.pdf (searched on Nov. 22, 2019)

### SUMMARY

### Technical Problem

According to the known technique, the LDPC is decoded based on a convex optimization method. According to the known technique, the LDPC is decoded by formulating a LDPC decoding problem as a convex programming problem and approximately solving the convex programming problem.

However, there is room for further improvement in processing related to decoding of the LDPC. For example, with a capability of converting a problem related to decoding as described above into a form of an Ising model, a solution can be obtained at a higher speed by an Ising machine such as a quantum computer that solves the problem using quantum annealing or an Ising calculator using a complementary metal-oxide-semiconductor (CMOS) or the like. Therefore, it is desired to make the Ising model applicable to processing related to decoding.

In view of this, the present disclosure proposes a conversion method, a conversion device, a reception device, and a transmission device that can make the Ising model applicable to processing related to encoding and decoding.

### Solution to Problem

According to the present disclosure, a conversion method of converting an objective function of combinatorial optimization related to encoding and decoding into a form of an Ising model, the conversion of the objective function into the form of the Ising model being performed by using the conversion method, the conversion method includes removing a modulo 2 operation from the objective function by using first transformation; replacing a first variable to be optimized included in the objective function with a second variable corresponding to an Ising spin by using second transformation; and reducing a degree of the second variable related to the objective function by using third transformation.

### BRIEF DESCRIPTION OF DRAWINGS

FIG. 1 is a diagram illustrating an example of processing performed by a communication system according to a first embodiment of the present disclosure.

FIG. 2 is a diagram illustrating a configuration example of a reception device according to the first embodiment of the present disclosure.

FIG. 3 is a diagram illustrating a configuration example of an Ising machine according to the first embodiment of the present disclosure.

FIG. 4 is a flowchart illustrating a procedure of decoding processing by the communication system.

FIG. 5 is a flowchart illustrating a procedure of conversion processing performed by the reception device.

FIG. 6 is a diagram illustrating an example of a configuration of the communication system.

FIG. 7 is a flowchart illustrating a procedure of decoding processing by the communication system.

FIG. 8 is a diagram illustrating an example of a Tanner graph.

FIG. 9 is a diagram schematically illustrating an Ising model.

FIG. 10 is a diagram schematically illustrating a tunnelling effect.

FIG. 11 is a diagram illustrating a configuration example of a reception device according to a second embodiment of the present disclosure.

FIG. 12 is a diagram illustrating an example of processing performed by a communication system according to a third embodiment of the present disclosure.

FIG. 13 is a diagram illustrating a configuration example of a transmission device according to the third embodiment of the present disclosure.

FIG. 14 is a diagram illustrating an example of a configuration of the communication system.

FIG. 15 is a flowchart illustrating a procedure of encoding processing performed by the communication system.

FIG. 16 is a conceptual diagram illustrating an example of application of the communication system.

FIG. 17 is a conceptual diagram illustrating an example of application of the communication system.

FIG. 18 is a hardware configuration diagram illustrating an example of a computer that implements functions of a conversion device, a reception device, and a transmission device.

### DESCRIPTION OF EMBODIMENTS

Embodiments of the present disclosure will be described below in detail with reference to the drawings. Note that the conversion method, the conversion device, the reception device, and the transmission device according to the present application are not limited by this embodiment. Moreover, in each of the following embodiments, the same parts are denoted by the same reference symbols, and a repetitive description thereof will be omitted.

The present disclosure will be described in the following order.
1. Technical overview
1-1. Channel coding technique
1-2. Error correction code
1-2-1. Low-Density Parity Check Code (LDPC)
1-3. Method of decoding LDPC
1-4. Tanner graph
2. First embodiment
2-1. Overview of processing by communication system according to first embodiment of present disclosure
2-1-1. Overview of configuration of communication system
2-1-2. Overview of processing in communication system
2-1-3. Quantum annealing and Ising machine
2-1-4. Conversion processing
2-1-4-1. Formulation of maximum likelihood decoding
2-1-4-2. First transformation (removal of mod 2 operation)
2-1-4-3. Second transformation (replacement with Ising spin)
2-1-4-4. Third transformation (degree reduction)
2-1-5. Optimization
2-1-6. Summary and others
2-2. Configuration of reception device according to first embodiment
2-3. Configuration of Ising machine
2-4. Procedure of information processing according to first embodiment
2-4-1. Procedure of decoding processing related to communication system
2-4-2. Procedure of conversion processing related to reception device
2-5. Example of configuration of communication system
2-5-1. Procedure of decoding processing related to communication system
3. Second embodiment
3-1. Conversion processing according to second embodiment
3-1-1. Formulation of maximum likelihood decoding
3-1-2. First transformation (removal of mod 2 operation)
3-1-3. Second transformation (replacement with Ising spin)
3-1-4. Third transformation (degree reduction)
3-1-5. Optimization
3-1-6. Summary and others
3-2. Configuration of reception device according to second embodiment
4. Third embodiment
4-1. Overview of processing by communication system according to third embodiment of present disclosure
4-1-1. Overview of configuration of communication system
4-1-2. Overview of processing in communication system
4-1-3. Conversion processing
4-1-3-1. Formulation
4-1-3-2. First transformation (removal of mod 2 operation)
4-1-3-3. Second transformation (replacement with Ising spin)
4-1-3-4. Third transformation (degree reduction)
4-1-3-5. Optimization
4-2. Configuration of transmission device according to third embodiment
4-3. Example of configuration of communication system
4-3-1. Procedure of encoding processing related to communication system
5. Other configuration examples, etc.
5-1. Other configuration examples
5-2. Comparison with known technique
5-2-1. Speed up searching coding method
5-2-2. Real time code generation
5-3. Application examples
5-3-1. Application example #1 (IoT)
5-3-2. Application example #2 (satellite communication)
5-4. Method of generating information used for processing program, parameter, and the like
5-5. Others
6. Effects according to the present disclosure
7. Hardware configuration

### 1. TECHNICAL OVERVIEW

As a preface of the present disclosure, an overview of the technical background according to the present disclosure will be described. In the following technical description, the description of the known technique will be omitted as appropriate.

### 1-1. Channel Coding Technique

Coding techniques include two known techniques of data compression and channel coding. Among these, channel coding is a technique used at performing data exchange (communication) via a channel. In channel coding, it is necessary to robustly restore data against disturbance in a channel. Therefore, contrary to data compression, coding for making data redundant is performed.

In a typical channel coding technique, a coding technique and a decoding technique are implemented as a set. In a communication system in which a coding technique and a decoding technique are implemented as a set, a transmission-side device (transmitter) includes a configuration such as an encoder or a modulator, and transmits information (signal) obtained by converting a transmission message using the encoder and the modulator to a reception-side device (receiver) via a channel. The receiver includes a configuration such as a demodulator and a decoder, converts received information (reception signal) using the demodulator and the decoder, and decodes a transmission message.

Here, the transmission message is a bit sequence of information desired to be transmitted. The encoder is a device that converts a transmission message into a bit string of a more redundant channel code. The modulator is a device that converts a channel code into a signal suitable for the channel. The modulator plays a role of superimposing a signal of a channel code on, for example, a carrier wave. The channel is a medium that transmits a signal. It is common with the channel that the quality of a signal deteriorates due to addition of noise or distortion of the signal during transmission. The demodulator is a device that converts a signal on a carrier wave into a signal of a channel code. The decoder is a device that reproduces a transmission message from a reception signal corresponding to a redundant channel code.

### 1-2. Error Correction Code

An error correction code is known as a technique related to the above-described encoder and decoder. For example, there is a known technique of performing decoding from a signal level of a reception signal using a probability, or techniques such as an LDPC code or a turbo code which, by being combined with the decoding techniques, can be applied to achieve a low error rate.

### 1-2-1. Low-Density Parity Check Code (LDPC)

The LDPC code is known as an error correction code using a low-density parity check matrix. The low-density parity check matrix is a matrix having a low appearance probability of an element (component) “1”, among a matrix that has only values of “0” or “1” which is referred to as a parity check matrix. The parity check matrix is a matrix that detects an error by multiplying the received code string. In the case of the binary linear code, the code string is represented by a bit string including bits having only values of “0” or “1”. The bit string is regarded as a vector and multiplied by a parity check matrix to generate a vector of check values. However, the matrix multiplication is a modulo with divisor 2. That is, similarly to the received code string and parity check matrix, the vector of the check value also has a value of “0” or “1” as an element. These are expressed by the following Formula (1).

$$( \begin{matrix}{c}_{1} \\ {c}_{2} \\ {c}_{3} \\ {c}_{4} \\ ⋮ \\ {c}_{K}\end{matrix} ) = ( \begin{matrix}1 & 0 & … & & 0 \\ 0 & & & & \\ ⋮ & & & & ⋮ \\ & & & & \\ & & & & \\ 0 & & … & & 1\end{matrix} ) ( \begin{matrix}{x}_{1} \\ {x}_{2} \\ {x}_{3} \\ {x}_{4} \\ {x}_{5} \\ {x}_{6} \\ {x}_{7} \\ ⋮ \\ {x}_{N}\end{matrix} ) mod 2 \qquad ( 1 )$$

Furthermore, on the right side of Formula (1), a matrix having elements of “0” or “1” indicates a parity check matrix H. For example, the parity check matrix H is a matrix of K rows and N columns. In addition, on the right side of Formula (1), x₁ to x_{N} indicate each element of a bit string xᵣ that has been received. For example, a subscript N is a number corresponding to the number of columns of the parity check matrix. On the left side In Formula (1), c₁ to c_{K} indicate individual elements of a vector c of the check value (check value vector c). For example, a subscript M is a number corresponding to the number of rows of the parity check matrix. Note that the number of elements of the vector of the check value may be different from the message length. For example, the subscript K may be a value different from M of the message length described below.

Regarding Formula (1), the vector c of the check value on the left side can be expressed as the following Formula (2) using the received bit string xᵣ and the parity check matrix H.

c=Hxᵣ mod 2 (2)

Here, a bit string to transmit is defined as a bit string xₜ. The bit string xₜ to transmit is generated so as to satisfy the constraint (all check values are “0”) as illustrated in the following Formula (3).

0=Hxₜ mod 2 (3)

Using each bit value xᵢ of the bit string xₜ, a component cₖ of the check value vector c is expressed as the following Formula (4).

$${c}_{k} = ( {\sum }_{i = 1}^{N} {h}_{ki} {x}_{i} ) mod 2 \qquad ( 4 )$$

When the received bit string xᵣ is the same as the transmitted bit string xₜ, that is, there is no error, the values of the individual elements of the check value vector c will be all “0”, that is, the check value vector c=0. When the check value vector c≠0, that is, the elements of the check value vector c include the value “1”, it indicates that the received bit string xᵣ includes an error. In this case, by inverting some bits of the received bit string xᵣ so as to achieve check value vector c=0, it is possible to return the transmitted bit string xₜ to any possible bit string xₜ.

### 1-3. Method of Decoding LDPC

The above has described an overview of the concept of the correction method using the check matrix of the received bit string. However, in decoding of LDPC, it is common to estimate an original transmission signal (bit string) from a reception signal string based on an analog value before being converted into a bit string. This is to avoid missing of information due to conversion of the reception signal into a bit string by directly using the reception signal in analog values.

The decoding of the LDPC is performed by using a technique referred to as belief propagation as decoding of the bit string from the analog reception signal. Specifically, the belief propagation first performs processing of obtaining information related to a likelihood ratio of a bit value, instead of a bit string, from the reception signal string. Subsequently, information regarding the likelihood of the check bit is obtained from the likelihood ratio, and then the likelihood ratio is corrected based on the information such that the check bit becomes “0”. This series of processing is repeated to calculate a bit string from the obtained likelihood ratio.

In the case of the Gaussian channel, “logarithmic odds” which is information regarding the likelihood ratio is calculated by the following Formula (5) using the noise level and the signal strength of the Gaussian channel, for example.

$${λ}_{j} = log \frac{p ( 0 \vert {r}_{j} )}{p ( 1 \vert {r}_{j} )} = \frac{2 {r}_{j}}{{n}^{2}} \qquad ( 5 )$$

Here, rⱼ is the strength of the j-th reception signal, and n is the level of noise. The reception signal of the Gaussian channel can be written as the following Formula (5-2).

rⱼ=xⱼ+nεⱼ (5-2)

Here, xⱼ is a signal in which the bit value of the transmitted code is a continuous value. Note that, in a case where the level of the noise is unknown, for example, a value around “1” or the like is appropriately set. Furthermore, p(0|rⱼ) indicates the probability that the j-th signal is “0”, and p(1|rⱼ) indicates the probability that the j-th signal is “1”, for example.

The processing of correcting the likelihood ratio is performed based on the following Formula (6), for example.

$${γ}_{j} = {λ}_{j} + {\sum }_{i} {h}_{ij} {a}_{ij} \qquad ( 6 )$$

γⱼ is the corrected logarithmic odds. Note that αᵢⱼ is an initial value “0”. That is, the initial value of γⱼ is the logarithmic odds λⱼ before correction of the j-th received signal. Furthermore, for example, hᵢⱼ corresponds to an element (component) of the i row and j column of a parity check matrix. The processing of calculating the correction value for correcting the likelihood ratio from the parity check matrix is performed based on the following Formulas (7), (8), and (9).

$${a}_{ij} = 2 {tanh}^{- 1} ( \frac{{δ}_{i}}{{β}_{ij}} ) \qquad ( 7 )$$

$${β}_{ji} = {γ}_{j} - {a}_{ij} \qquad ( 8 )$$

$${δ}_{i} = {\prod }_{j} ( 1 - {h}_{ij} + {h}_{ij} tanh ( \frac{1}{2} {β}_{ji} ) ) \qquad ( 9 )$$

Iterating this processing an appropriate number of times can calculate the logarithmic odds γⱼ of the posterior probability in consideration of the parity constraint. By performing determination on the logarithmic odds using a threshold, the original transmission code string is estimated. In this manner, by iterating the processing using Formulas (5) to (9) with feedback of the correction value for correcting the likelihood ratio, the likelihood ratio is corrected so as to satisfy the parity check matrix. Since the likelihood ratio is corrected so as to satisfy the parity check matrix, it is possible to perform decoding in which the influence of the noise of the channel is suppressed while satisfying the code condition with a predetermined threshold.

### 1-4. Tanner Graph

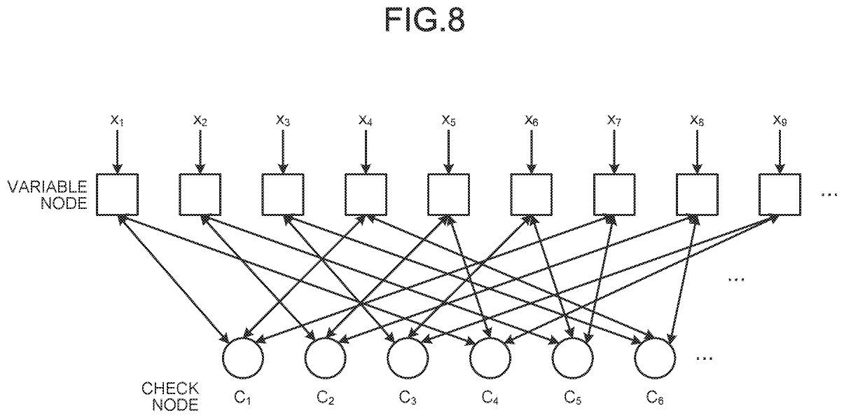

Here, as a method of graphically representing a parity check matrix, a bipartite graph referred to as a Tanner graph is known. For example, it is assumed to have a bipartite graph in which an element of the code bit string on the right side and an element of the check bit string on the left side of the above Formula (1) are defined as nodes, with a node of the code bit string being defined as a variable node and a node of the check bit string being defined as a check node. In this bipartite graph, a graph forming by connecting only an edge (side) corresponding to a portion where the element of the parity check matrix is “1” is referred to as a Tanner graph. An example of the Tanner graph is illustrated in FIG. 8. FIG. 8 is a diagram illustrating an example of a Tanner graph.

The processing of Formulas (6) and (7) in the SumProduct method described above corresponds to processing of a variable nodes on the Tanner graph. In addition, the processing of Formulas (8) and (9) corresponds to the processing of the check nodes on the Tanner graph.

In the SumProduct method, it is known that decoding performance is often deteriorated when a Tanner graph includes a short loop. Here, the loop is a path starting from a certain variable node, repeatedly passing through check nodes and variable nodes, and returning to the original variable node.

In the LDPC, the code is formed by the configuration of the check matrix, but the configuration of the check matrix is performed by using a random number, and the accuracy of the code is evaluated by actually performing simulation. Furthermore, this process further includes processing such as avoidance of a loop in the Tanner graph. These types of processing would be applicable to cases where there is a time allowed for a search performed over time using a method in which a good check matrix once found is to be utilized repeatedly as in current applications. However, in a case where it is desired to quickly generate a code in real time, or it is desired to frequently form a new code according to an application, for example, it is desirable to avoid such trial-and-error time. Furthermore, there is another problem that the degree of performance deterioration due to the presence of the Tanner graph is not known. With an evaluation performed by more purified methods such as an inter-code minimum distance or a bounded distance, it is possible to achieve improvement of codes, and reduction of constraints, with more suitability for automation of a code configuration.

As described above, the LDPC has not been suitable for configuring a good code in real time, constructing a code according to an application (specifically the occurrence frequency distribution of messages generated in the application), or simplifying the configuration of a code by evaluating, with a purified method, the performance of a code based on an inter-code distance so as to improve the performance of a code having a short code length that is hardly close to the Shannon channel capacity, for example.

Therefore, there has been a demand for providing a method capable of generating a code that does not need to avoid loop avoidance of the Tanner graph, a method capable of generating a code that only needs to evaluate an inter-code distance with a purified manner, and the like.

In view of this, the present disclosure proposes a method capable of making the Ising model applicable to processing related to encoding and decoding.

### 2. FIRST EMBODIMENT

### 2-1. Overview of Processing by Communication System According to First Embodiment of Present Disclosure

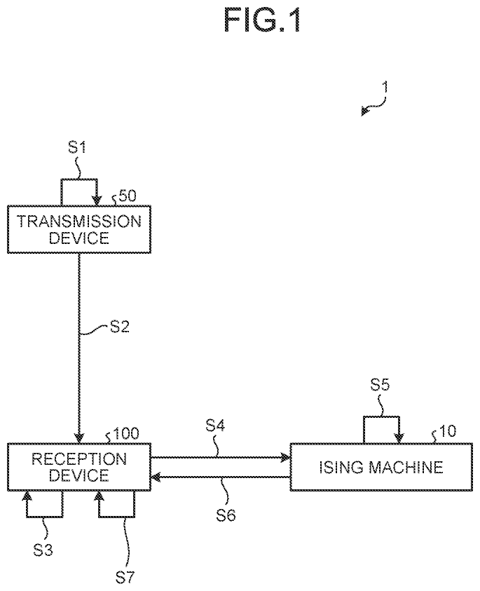

FIG. 1 is a diagram illustrating an example of processing performed by a communication system according to a first embodiment of the present disclosure. The processing according to the first embodiment of the present disclosure is implemented by a reception device 100 which is an example of a conversion device illustrated in FIG. 1. Note that the reception device 100 may be a communication device that performs not only the reception of information but also communication with other devices including transmission/reception of information. In this case, the reception device 100 functions as a transmission device that transmits information to other devices.

### 2-1-1. Overview of Configuration of Communication System

First, a configuration of a communication system 1 illustrated in FIG. 1 will be described. FIG. 1 illustrates a configuration example of a communication system 1 according to the first embodiment. As illustrated in FIG. 1, the communication system 1 includes an Ising machine 10, a transmission device 50, and a reception device 100. The transmission device 50 corresponds to a transmission-side device (transmitter), and the reception device 100 corresponds to a reception-side device (receiver). The example of FIG. 1 illustrates a case where the Ising model is used for decoding the information in the reception device 100 being a reception-side device (receiver). Note that the communication system 1 illustrated in FIG. 1 may include a plurality of Ising machines 10, a plurality of transmission devices 50, and a plurality of reception devices 100.

The transmission device 50 and the reception device 100 are communicably connected by wire or wirelessly via a predetermined network (communication network). The transmission device 50 transmits information (signal) to the reception device 100 via a channel by a predetermined network. In addition, the Ising machine 10 and the reception device 100 are communicably connected to each other by wire or wirelessly via a predetermined network (communication network).

The Ising machine 10 is a computer (calculator) using an Ising model. The Ising machine 10 is a computer that solves a combinatorial optimization problem using an Ising model. In the example of FIG. 1, the Ising machine 10 is a quantum computer (quantum calculator) that solves a problem using quantum annealing. The Ising machine 10 can be implemented by a quantum annealing system or a quantum annealer. Note that the Ising machine 10 is not limited to a computer referred to as a quantum computer, and may be any computer such as an Ising calculator using a complementary metal-oxide-semiconductor (CMOS) or the like, as long as it is a computer using an Ising model. For example, the Ising machine 10 may be an Ising calculator using a processor such as a graphics processing unit (GPU) or using an integrated circuit such as a field programmable gate array (FPGA).

The transmission device 50 is a transmission-side device (transmitter) that transmits information to another device. Note that the transmission device 50 may be a communication device that performs not only the transmission of information but also communication with other devices including transmission/reception of information. In this case, the transmission device 50 functions as a transmission device that transmits information to other devices. The transmission device 50 transmits information to another device via a network (channel).

The transmission device 50 is an information processing device that performs encoding. The transmission device 50 has a function of encoding information (message) to be transmitted. The transmission device 50 generates a codeword (code string) obtained by encoding a message by using a channel coding technique. The transmission device 50 performs encoding using a generator matrix and generates a codeword obtained by encoding the message. The transmission device 50 transmits the codeword obtained by encoding the message to another device such as the reception device 100.

The reception device 100 is a reception-side device (receiver) that receives information from another device. The reception device 100 decodes information received from another device into original information.

The reception device 100, which is a conversion device, converts a target objective function related to decoding in channel coding into a form of an Ising model. The reception device 100 converts an objective function being a target related to decoding of a linear code into the form of the Ising model.

The reception device 100 converts an objective function to be used for decoding information received by the communication device from another communication device into the form of the Ising model. The reception device 100 converts an objective function used for decoding information transferred between communication devices into the form of an Ising model. The reception device 100 converts a target objective function being a message into the form of the Ising model. The reception device 100 converts an objective function corresponding to the maximum likelihood decoding into the form of the Ising model. The reception device 100 converts an objective function including a variable corresponding to a generator matrix of encoding into the form of the Ising model. The reception device 100 converts the objective function including the variable corresponding to the check matrix into the form of the Ising model.

The reception device 100 instructs the Ising machine 10 to execute calculation. The reception device 100 transmits the parameters of the Ising model to the Ising machine 10. By transmitting the parameters of the Ising model to the Ising machine 10, the reception device 100 instructs the Ising machine 10 to execute calculation. The reception device 100 acquires a calculation result of the Ising machine 10. The reception device 100 receives a calculation result of the Ising machine 10 from the Ising machine 10. Using the calculation result of the Ising machine 10 acquired from the Ising machine 10, the reception device 100 executes decoding processing and generates decoded information.

### 2-1-2. Overview of Processing in Communication System

Here, an overview of processing of the communication system 1 will be described with reference to FIG. 1. The example of FIG. 1 illustrates a case where information (data) is transmitted from the transmission device 50 to the reception device 100, as an example.

The transmission device 50 encodes a message (message MX) using the channel encoding technique (step S1). The transmission device 50 encodes the message MX by using LDPC coding. With this method, the transmission device 50 generates a codeword (codeword CT) obtained by encoding the message MX. The transmission device 50 transmits a codeword CT to the reception device 100 via the channel (step S2). Accordingly, the reception device 100 receives a codeword CT′ corresponding to the codeword CT. For example, the reception device 100 receives the codeword CT′ produced as a result of channel noise mixed in the codeword CT.

The reception device 100 converts the objective function related to decoding into a form that can be calculated by the Ising machine 10 (step S3). The reception device 100 performs conversion processing for converting the objective function into the form of the Ising model. The reception device 100 removes a modulo 2 operation from the target objective function related to decoding, replaces a first variable corresponding to the target included in the objective function with a second variable corresponding to an Ising spin, and reduces the degree of the second variable, and thereby converts the objective function into the form of the Ising model. Details of this conversion processing will be described below in [2-1-4. Conversion processing]. In order to simplify the description, the example of FIG. 1 uses a case where the reception device 100 performs the conversion processing after receiving the information. However, processing executable before reception in the conversion processing may be performed in advance, or may be performed by another conversion device, that is, a device other than the reception device 100. For example, the first variable is a variable constituting a message to be restored. For example, the first variable is a variable constituting the codeword to be decoded. For example, the objective function of the combinatorial optimization is an objective function of the maximum likelihood decoding regarding the first variable. In addition, for example, the objective function of combinatorial optimization is an objective function of maximum likelihood decoding using a generator matrix. Furthermore, for example, the objective function of combinatorial optimization is an objective function of maximum likelihood decoding having a constraint of parity check regarding a codeword as a constraint term.

Subsequently, the reception device 100 instructs the Ising machine 10 to execute calculation by using the information of the objective function after being converted into the form of the Ising model (step S4). The reception device 100 transmits the parameters of the Ising model to the Ising machine 10. By transmitting the parameter of the objective function after being converted into the form of the Ising model to the Ising machine 10, the reception device 100 instructs the Ising machine 10 to execute calculation.

After having acquired the parameter from the reception device 100, the Ising machine 10 executes calculation (step S5). For example, the Ising machine 10 obtains a solution of a combinatorial optimization problem of minimizing an objective function by a technique such as quantum annealing, details of which will be described below in [2-1-3. Quantum annealing and Ising machine].

Subsequently, the Ising machine 10 transmits the calculation result (measurement result) to the reception device 100 (step S6). With this operation, the reception device 100 acquires the calculation result of the Ising machine 10.

The reception device 100 then executes decoding processing using the calculation result of the Ising machine 10 acquired from the Ising machine 10 so as to generate decoded information (step S7). For example, the reception device 100 decodes the message MX by executing the decoding processing using the calculation result of the Ising machine 10 acquired from the Ising machine 10.

As described above, the reception device 100 performs the conversion processing for converting the objective function into the form of the Ising model and thereby converts the objective function into a form that can be calculated by the Ising machine 10. In this manner, the communication system 1 can apply the Ising model to processing related to encoding and decoding. With this configuration, the communication system 1 can perform decoding at high speed by using the Ising machine 10.

### 2-1-3. Quantum Annealing and Ising Machine

Here, the Ising machine 10 will be described. First, as an example of the Ising machine 10, and a quantum annealer as a device to perform quantum annealing will be described.

Quantum annealing is known as a hardware system that performs combinatorial optimization using quantum bits (also referred to as Qbit or Qubit) using quantum devices. Here, the quantum bit is an information unit (bit) that can implement quantum superposition and quantum entanglement. For example, quantum superposition is a phenomenon in which two states (values) are stochastically (quantum probability amplitude) held in parallel with one bit (1 Qbit), while quantum entanglement is a phenomenon implementing a correlation state that cannot be classically implemented between two bits.

Since quantum annealing is a type of calculation using a quantum bit, it is often confused with quantum calculation, but its operation is considerably different from that of a quantum computer that has been conventionally examined. However, since quantum annealing can still be referred to as calculation using quantum bits, it is often regarded as one method of quantum calculation.

The calculation that can be implemented by quantum annealing is finding a solution to a combinatorial optimization problem that minimizes an objective function in a quadratic form as in the following Formula (10).

$$L = - {\sum }_{ij} {J}_{ij} {σ}_{i} {σ}_{j} + {\sum }_{k} {h}_{k} {σ}_{k} \qquad ( 10 )$$

Here, σᵢ is a variable that has either a binary value of “0” or “1”, and is a variable for which an optimal solution is to be found. Similarly, σⱼ and σₖ are variables that has either binary values of “0” and “1”, and are variables for which an optimal solution is to be found. Further, Jᵢⱼ and hₖ are parameters and are given from the outside. For example, the Ising machine 10 acquires parameters Jᵢⱼ and hₖ from another device such as the reception device 100. For sake of description, these parameters are parameters when σᵢ is “±1”, that is, being “−1” or “1” instead of “0” or “1” for convenience.

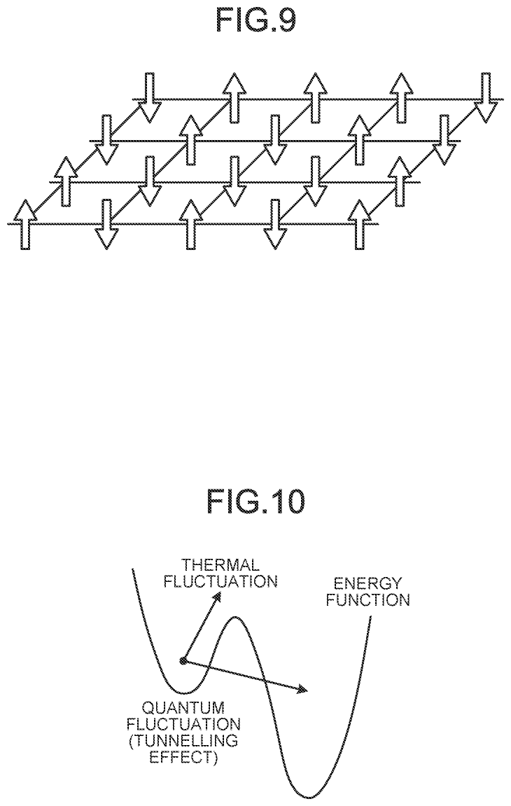

In quantum annealing, first, a physical model referred to as an Ising model is implemented using a quantum device and a circuit. For example, the Ising model, when represented by an illustration, can be a drawing as illustrated in FIG. 9. FIG. 9 is a diagram schematically illustrating an Ising model.

The Ising model is a physical model proposed as a simple model for demonstrating the ferromagnetism of the magnet. In FIG. 9, each grid point represents an electron spin at which only an upward or downward spin moment is observed.

In statistical physics, behavior of a physical model is described using an energy function, and the energy function (Hamiltonian) of this physical model is described as the following Formula (11).

$${H}_{Ising} = - {\sum }_{i , j} {J}_{ij} {σ}_{i}^{z} {σ}_{j}^{z} + {\sum }_{k} {h}_{k} {σ}_{k}^{z} \qquad ( 11 )$$

In Formula (11), σᵢ is the i-th spin. σᵢ is a variable indicating whether the spin is upward “−1” or downward “1”. Similarly, σⱼ and σₖ are variables indicating whether the spin is upward “−1” or downward “1”. In addition, Jᵢⱼ is a binding energy that determines the magnitude of the interaction between spins, and hₖ is an external magnetic field component parallel to the spins. Regarding the binding energy between the spins, a model in which only the binding energy between adjacent spins is set to a value other than “0” is adopted as a model for demonstrating the ferromagnetism of a magnet. However, the model is generalized here such that the binding energy can have a value other than “0” between certain spins. Such a model is referred to as spin glass. Note that Jᵢⱼ or hₖ may be referred to as a parameter of the Ising model or a coefficient of the Ising model, but may be simply referred to as a parameter.

As indicated in Formulas (10) and (11), the energy function of the Ising model is equivalent to the objective function of the combinatorial optimization. For example, the point that the energy function of the Ising model is equivalent to the objective function of the combinatorial optimization can be proved by processing such as change of variables between “±1” and “0”, and “1”, but detailed description thereof is omitted. This had been an origin of the idea of quantum annealing, that is, artificially making an Ising model having the same parameters as the parameters of the objective function of the combinatorial optimization and measuring the spin of the ground state (minimum state of energy) of the energy function will lead to an optimal solution (global optimum instead of local optimum).

The minimum state of energy is implemented by stepwise adiabatic transition (state transition that is slow enough to be regarded as a steady state) from the superposed state to the ground state at an ultra-low temperature. This process is referred to as quantum annealing.

Specifically, first, at an initial stage, a transverse magnetic field (horizontal magnetic field) as expressed in the following Formula (12) for implementing the superposed state of all combinations is applied.

$${H}_{Quantum} = Γ {\sum }_{k} {σ}_{k}^{x} \qquad ( 12 )$$

An energy function (Hamiltonian) to which a transverse magnetic field is applied as in Formula (12) is as expressed in Formula (13) below.

$${H}_{QA} ( t ) = \frac{t}{T} {H}_{Ising} + ( 1 - \frac{t}{T} ) {H}_{Quantum} \qquad ( 13 )$$

In Formula (13), the initial state is a state in which a term including the transverse magnetic field H_{Quantum} (superposition term) is dominant and all combinations (solution candidates) are superposed. For example, in Formula (13), in the state t=0, the superposition term is dominant, and all combinations (solution candidates) are superimposed. In Formula (13), the superposition term is then loosened stepwise (for example, by increasing t) so as to be converged to the solution at the time T, achieving the ground state. Thereafter, the spin is measured in the ground state to be used as the optimal solution. Since these procedures are implemented by using known techniques of quantum annealing, detailed description thereof is omitted.

In addition, while this process includes a “slow” adiabatic process, it is possible, in an actual machine (for example, the Ising machine 10), to complete the entire process in units of microseconds.

In addition, as compared with the simulated annealing using thermal fluctuation, the processing uses the tunnelling effect by the quantum fluctuation as illustrated in FIG. 10, leading to an expectation of achievement of the state at a higher speed compared to the simulated annealing. FIG. 10 is a diagram schematically illustrating the tunnelling effect. Note that the effect is also experimentally verified in a specific problem setting.

Known examples of a quantum device that implements quantum bits include ions, light, and single electrons (quantum dots). However, the quantum device currently considered to be most effective is a superconducting device. In order to implement superconductivity, a cryogenic cooling is required. This has conventionally required huge cooling devices (cooling mechanism), and these cooling devices can be installed on the server side so as to obtain simply a calculation result on the edge side.

For example, the communication system 1 can be configured, for example, such that the Ising machine 10 including a cooling mechanism is arranged on the server side, and the reception device 100 on the edge side requests calculation from the Ising machine 10 and acquires a calculation result, so that the reception device 100 on the edge side can obtain only the calculation result.

In addition, with the implementation of quantum annealing, combinatorial optimization using the Ising model has attracted attention, which has led to a proposal of a device that speeds up the operation of combinatorial optimization represented by the Ising model by using an existing digital circuit or gate circuit without using a quantum bit. An example of this is an Ising calculator using a CMOS or the like. Since these can be implemented by a digital circuit without using superconductivity, making it possible to be implemented also on the edge side.

As described above, the Ising machine 10 may be a device (Ising calculator) that uses an existing digital circuit or gate circuit. That is, the Ising machine 10 may be an Ising calculator using a processor such as a GPU or an integrated circuit such as an FPGA.

### 2-1-4. Conversion Processing

Hereinafter, a conversion method will be described. Here, LDPC (LDPC code) will be described as an example. Note that the conversion processing and the like described below are only assumed to have a linear code of mod 2, and the application target is not limited to LDPC. That is, the conversion processing can be applied to a maximum likelihood decoding method of a general mod 2 linear code. For example, the application target may be various encoding methods such as a Reed-Solomon code, a Hamming code, and a Bose-Chaudhuri-Hocquenghem (BCH) code.

### 2-1-4-1. Formulation of Maximum Likelihood Decoding

First, the premise will be described. Encoding performed by the LDPC uses a generator matrix that can be calculated (generated) from a check matrix. Not limited to the case of LDPC, the generator matrix of the binary linear code is a matrix including only elements of “0” or “1”, and is an N×M matrix in which the message length is M and the code length is N. For example, the matrix can be expressed as the following Formula (14).

$$( \begin{matrix}{x}_{1} \\ {x}_{2} \\ {x}_{3} \\ {x}_{4} \\ {x}_{5} \\ {x}_{6} \\ {x}_{7} \\ ⋮ \\ {x}_{N}\end{matrix} ) = ( \begin{matrix}1 & 0 & … & & 0 \\ 0 & & & & \\ & & & & \\ & & & & \\ ⋮ & & & & ⋮ \\ & & & & \\ & & & & \\ & & & & \\ 0 & & … & & 0\end{matrix} ) ( \begin{matrix}{m}_{1} \\ {m}_{2} \\ {m}_{3} \\ {m}_{4} \\ ⋮ \\ {m}_{M}\end{matrix} ) mod 2 \qquad ( 14 )$$

On the right side of Formula (14), a matrix having “0” or “1” as elements indicates a generator matrix G. For example, the generator matrix G is a matrix of N rows and M columns. On the right side of Formula (14), m₁ to m_{M} indicate individual elements of a message m. For example, a subscript M is a number corresponding to the number of columns of the generator matrix. Note that the number of elements of the message (message length) may be different from the number of elements of the vector of the check value described above. On the right side of Formula (14), mod 2 represents a modulo 2 operation. For example, mod 2 corresponds to an operation of dividing by a modulus “2” and acquiring a remainder. In addition, on the left side of Formula (14), x₁ to x_{N} represent elements of a codeword x. For example, the subscript N is a number corresponding to the number of rows of the generator matrix.

Regarding Formula (14), the codeword x on the left side can be expressed by Formula (15) below using the message m and the generator matrix G.

x=Gm mod 2 (15)

Furthermore, Formula (15) can be expressed as the following Formula (16).

$${x}_{i} = ( {\sum }_{j = 1}^{M} {g}_{ij} {m}_{j} ) mod 2 \qquad ( 16 )$$

Here, x=(x₁ . . . x_{N}) is a bit string (codeword) representing a code, and m=(m₁ . . . m_{M}) is a bit string representing a message. Further, gᵢⱼ corresponds to an element (component) of i row and j column of the generator matrix G.

The maximum likelihood decoding is a decoding method of finding a bit string of the most likely message for the received signal sequence. Generally, white additive Gaussian noise is considered as the disturbance in the channel. In such a channel model, the reception signal can be written by the following Formula (16-2).

rⱼ=xⱼ+nεⱼ (16-2)

Here, xⱼ is a signal in which the bit value of the transmitted code is a continuous value. When maximum likelihood decoding is performed on a message from a reception signal according to such a model, the maximum likelihood decoding is formulated as a least squares method as in the following Formula (17).

$${m}^{*} = {arg min}_{m} {\sum }_{i = 1}^{N} {( {r}_{i} - {x}_{i} )}^{2} \qquad ( 17 )$$

In Formula (17), xᵢ represents an i-th value of the codeword (bit string). In Formula (17), rᵢ represents a received signal. For example, rᵢ in Formula (17) indicates a signal having noise included in the transmitted codeword. In Formula (17), xᵢ represents a value including noise added to the i-th value of the codeword (bit string). Furthermore, Formula (17) can be expressed as the following Formula (18).

$${m}^{*} = {arg min}_{m} {\sum }_{i = 1}^{N} {( {r}_{i} - ( {\sum }_{j = 1}^{M} {g}_{ij} {m}_{j} ) mod 2 )}^{2} \qquad ( 18 )$$

Since there is a mod 2 operation in the least squares method as expressed in Formula (18), it is necessary to examine all combinations regarding m. That is, there are 2^{M} combinations. On the other hand, when there is no mod 2 operation, this equation corresponds to a quadratic expression of m. In this case, it can be expected that the above-described combinatorial optimization formula can be applied. In practice, however, since there is a mod 2 operation, the formula cannot be directly applied.

To handle this issue, by performing the transformation processing including the first to third transformations as described below on Formula (18) being the objective function, the reception device 100 removes mod 2 and converts the objective function into the form of the Ising model.

### 2-1-4-2. First Transformation (Removal of Mod 2 Operation)

First, reception device 100 removes the mod 2 operation by using the first transformation. Since gᵢⱼ and mⱼ can only be either “0” or “1”, the mod 2 operation can be transformed as expressed in the following Formula (19).

$$( {\sum }_{j = 1}^{M} {g}_{ij} {m}_{j} ) mod 2 = \frac{1}{2} ( 1 - {\prod }_{j = 1}^{M} ( 1 - 2 * {g}_{ij} {m}_{j} ) ) \qquad ( 19 )$$

Here, the proof of the above transformation will be briefly described. First, with assumption a, b E {0, 1}, all combinations (four patterns) are considered for attempt, which leads to establishment of a lemma as expressed in the following Formula (20).

$$( a + b ) mod 2 = \frac{1}{2} ( 1 - ( 1 - 2 * a ) ( 1 - 2 * b ) ) \qquad ( 20 )$$

Subsequently, the above relational expression (Formula (19)) will be proved by mathematical induction. When M=1, the above relational expression holds as expressed in the following Formula (21).

$$\frac{1}{2} ( 1 - {\prod }_{j = 1}^{M} ( 1 - 2 * {g}_{i j} {m}_{j} ) ) = \frac{1}{2} ( 1 - ( 1 - 2 * {g}_{i 1} {m}_{1} ) ) = {g}_{i 1} {m}_{1} = {g}_{i 1} {m}_{1} mod 2 \qquad ( 21 )$$

Next, it is assumed that the above relational expression (Formula (19)) holds for M. The left side in the case of M+1 can be transformed as in the following Formula (22).

$${\sum }_{j = 1}^{M + 1} {g}_{i j} {m}_{j} mod 2 = ( {g}_{i M + 1} {m}_{M + 1} + ( {\sum }_{j = 1}^{M} {g}_{i j} {m}_{j} ) mod 2 ) mod 2 \qquad ( 22 )$$

In addition, Formula (22) can be transformed into the following Formula (23) from Formula (19).

$${\sum }_{j = 1}^{M + 1} {g}_{i j} {m}_{j} mod 2 = ( {g}_{i M + 1} {m}_{M + 1} + \frac{1}{2} ( 1 - {\prod }_{j = 1}^{M} ( 1 - 2 * {g}_{i j} {m}_{j} ) ) ) mod 2 \qquad ( 22 )$$

Next, Formula (23) can be transformed to Formula (24) below based on the lemma.

$${\sum }_{j = 1}^{M + 1} {g}_{i j} {m}_{j} mod 2 = \frac{1}{2} ( 1 - ( 1 - 2 {g}_{i M + 1} {m}_{M + 1} ) ( 1 - ( 1 - {\prod }_{j = 1}^{M} ( 1 - 2 * {g}_{i j} {m}_{j} ) ) ) ) = \frac{1}{2} ( 1 - {\prod }_{j = 1}^{M + 1} ( 1 - 2 * {g}_{i j} {m}_{j} ) )$$

(24)

It is known that, when the above relational expression holds for M, the relational expression can hold also for M+1. Accordingly, Formula (25) (same as Formula (18) above), which is the optimization expression of the maximum likelihood decoding, can be transformed into the formula not including the mod 2 as in the following Formula (26).

$${m}^{*} = {arg min}_{m} {{\sum }_{i = 1}}^{N} {( {r}_{i} - ( {\sum }_{j = 1}^{M} {g}_{i j} {m}_{j} ) mod 2 )}^{2} \qquad ( 25 )$$

$${m}^{*} = {arg min}_{m} {{\sum }_{i = 1}}^{N} {( {r}_{i} - \frac{1}{2} ( 1 - {\prod }_{j = 1}^{M} ( 1 - 2 * {g}_{i j} {m}_{j} ) ) )}^{2} \qquad ( 26 )$$

With expansion of the term of the square of Formula (26), it can be transformed as the following Formula (27).

$${m}^{*} = {arg min}_{m} {\sum }_{i = 1}^{N} ( {( {r}_{i} - \frac{1}{2} )}^{2} + ( {r}_{i} - \frac{1}{2} ) {\prod }_{j = 1}^{M} ( 1 - 2 * {g}_{i j} {m}_{j} ) + \\ {( \frac{1}{2} {\prod }_{j = 1}^{M} ( 1 - 2 * {g}_{i j} {m}_{j} ) )}^{2} ) \qquad ( 27 )$$

Here, in the right side E of Formula (27), the first term and the third term are constants independent of mⱼ (for example, the third term is always ¼), and thus, Formula (27) can be transformed into the following Formula (28).

$${m}^{*} = {arg min}_{m} {\sum }_{i = 1}^{N} ( {r}_{i} - \frac{1}{2} ) {\prod }_{j = 1}^{M} ( 1 - 2 * {g}_{i j} {m}_{j} ) \qquad ( 28 )$$

In this manner, Formula (28) does not include the mod 2 operation. By using the first transformation, the reception device 100 converts the form of the objective function from Formula (18) into Formula (28) to remove the mod 2 operation.

### 2-1-4-3. Second Transformation (Replacement with Ising Spin)

Next, the reception device 100 performs replacement with an Ising spin by using the second transformation. The reception device 100 performs replacement with the Ising spin by using the conversion equation “σⱼ=1−2mⱼ”. For example, the reception device 100 replaces a first variable “m” corresponding to the message with a second variable “a” corresponding to the Ising spin. The reception device 100 transforms Formula (28) into Formula (29) below by using the conversion equation “σⱼ=1−2mⱼ”.

$${σ}^{*} = {arg min}_{σ} {\sum }_{i = 1}^{N} ( {r}_{i} - \frac{1}{2} ) {\prod }_{j = 1}^{M} ( 1 - {g}_{i j} + {g}_{i j} {σ}_{j} ) \qquad ( 29 )$$

An objective function in the form of Formula (29) is a polynomial of degree M regarding σⱼ. Since gᵢⱼ is “0” or “1”, Formula (29) can be transformed as the following Formula (30).

$${σ}^{*} = {arg min}_{σ} {\sum }_{i = 1}^{N} ( {r}_{i} - \frac{1}{2} ) {\prod }_{k = 1}^{{M}_{i}} {σ}_{{i}_{k}} \qquad ( 30 )$$

Here, Mᵢ is the number of “1” in the i row of the generator matrix. In addition, iₖ is an index number of a column in which “1” appears k-th from the left in the i row of the generator matrix.

In this manner, in Formula (30), the first variable “mⱼ” corresponding to the message has been replaced with the second variable “σⱼ” corresponding to the Ising spin. The reception device 100 converts the form of the objective function from Formula (28) to Formula (30) by the second transformation, and replaces the first variable corresponding to the target with the second variable corresponding to the Ising spin.

### 2-1-4-4. Third Transformation (Degree Reduction)

The optimization problem as expressed in Formula (30) may be a quadratic or higher polynomial regarding σ. However, in the Ising model, the objective function is a quadratic polynomial regarding σ. Therefore, in order to solve this optimization problem by optimization of the Ising model, it is necessary to reduce the degree to a quadratic expression regarding σ. Accordingly, the reception device 100 reduces the degree of the second variable “σ” by the third transformation.

Since the product σᵢσⱼ is a variable being “−1” or “1”, the product can be replaced with a variable σₚ, for example. With this operation, the reception device 100 can lower the degree regarding σ by one. However, it is necessary to ensure consistency between σᵢ and σⱼ used in other situations, and σₚ. Therefore, for example, the reception device 100 adds a constraint term as illustrated in the following Formula (31) to the objective function.

H=3σₚ+σᵢσⱼ−2σᵢσₚ−2σⱼσₚ (31)

This constraint term has high energy when σᵢσⱼ≠σₚ. Therefore, by multiplying this term by a positive constant and adding the result to the objective function, the solution is obtained under the constraint of σᵢσⱼ=σₚ. Note that the constraint term is not limited to the above expression, and may be variously set within a range of the quadratic form as long as the constraint term is an expression in which the energy is “0” only when σᵢσⱼ=σₚ, and is positive in a case other than σᵢσⱼ=σₚ.

For example, the reception device 100 reduces the degree of the second variable “σ” of Formula (30) while adding the constraint term of Formula (31). Hereinafter, a method of sequentially lowering the degree of the second variable “σ” of Formula (30) will be described using Formula (31). For example, new spins σₚₘ (m=2 . . . Mᵢ) are sequentially introduced as in the following Formulas (32), (32-2), (32-3), and (32-4) for the term of the product of the dimension of Mᵢ regarding the ith bit so as to reduce the dimension of the product.

$${\prod }_{k = 1}^{{M}_{i}} {σ}_{{i}_{k}} = {σ}_{{i}_{1}} {σ}_{{i}_{2}} {σ}_{{i}_{3}} … {σ}_{{M}_{i}} \qquad ( 32 )$$

$$= {σ}_{{p}_{2}} {σ}_{{i}_{3}} … {σ}_{{M}_{i}} , ( {σ}_{{p}_{2}} = {σ}_{{i}_{1}} {σ}_{{i}_{2}} ) \qquad ( 32 ‐ 2 )$$

$$= {σ}_{{p}_{m}} {σ}_{{i}_{m + 1}} … {σ}_{{M}_{i}} , ( {σ}_{{p}_{m}} = {σ}_{{p}_{m - 1}} {σ}_{{i}_{m}} ) \qquad ( 32 ‐ 3 )$$

$$= {σ}_{{p}_{{M}_{i}}} ( {σ}_{{p}_{{M}_{i}}} = {σ}_{{p}_{{M}_{i} - 1}} {σ}_{{i}_{{M}_{i}}} ) \qquad ( 32 ‐ 4 )$$

Formula (32-2) represents a case where the degree is reduced by 1 from Formula (32). Specifically, Formula (32-2) represents a case where the degree of the second variable “σ” is reduced by 1 from Formula (32) by defining the product of σᵢ₁ and σᵢ₂ to σₚ₂. This makes it possible to reduce the dimension of the optimization Formula (30) to one dimension as expressed in the following Formula (33).

$${σ}^{*} = {arg min}_{σ} {\sum }_{i = 1}^{N} ( {r}_{i} - \frac{1}{2} ) {σ}_{{p}_{{M}_{i}}} \qquad ( 33 )$$

However, the newly introduced spins satisfy the constraints of quadratic expressions as expressed in the following expressions (34) and (35) similar to Formula (31).

H_{i,2}=3σₚ_{₂}+σᵢ_{₁}σᵢ_{₂}−2σᵢ_{₁}σₚ_{₂}−2σᵢ_{₂}σₚ_{₂} (34)

Hᵢₘ=3σₚ_{ₘ}+σₚ_{ₘ₋₁}σᵢ_{ₘ}−2σₚ_{ₘ₋₁}σₚ_{ₘ}−2σᵢ_{ₘ}σₚ_{ₘ} (35)

When the optimization Formula (30) is transformed into a form of a Lagrange multiplier so as to satisfy this constraint, the following Formula (36) is obtained.

$${σ}^{*} , {σ}_{p}^{*} = {arg min}_{σ , {σ}_{p}} {\sum }_{i = 1}^{N} ( ( {r}_{i} - \frac{1}{2} ) {σ}_{{p}_{{M}_{i}}} + {\sum }_{m = 2}^{{M}_{i}} {λ}_{i m} {H}_{i m} ) \qquad ( 36 )$$

The parameter λᵢₘ, which is a multiplier, is a positive value. Here is a case where different parameters are used for each constraint expression. However, since all the above constraint expressions have only values of “0” or more, the same multiplier may be used.

In order to ensure that the constraint condition is satisfied, the parameter λ^{im} is desirably a large value, for example, a value of “1” or more. For example, it is desirable to set the second term as the constraint term to be about six times the first term.

Alternatively, the parameter may be set slightly smaller at the beginning and repeatedly increased until the constraint term becomes “0”. The parameter λᵢₘ may be increased by a gradient method as in the following Formula (37). Note that γ is a small positive value and is an update parameter of the gradient method.

λᵢₘ←λᵢₘ+γHᵢₘ (37)

Here, Formula (36) includes only the terms of quadratic expressions regarding the spin. In this manner, it is possible to derive an energy function (Hamiltonian) of the Ising model equivalent to the objective function of the maximum likelihood decoding. In this manner, the reception device 100 transforms Formula (18) of the objective function of the maximum likelihood decoding into the form of the Ising model, that is, the Formula (36) corresponding to the Hamiltonian of the Ising model.

### 2-1-5. Optimization

Subsequently, in the optimization, the coefficient of the Ising model is given to the Ising machine 10 for calculating annealing, and a resultant Ising spin is used as a basis to generate (decode) a message. For example, the reception device 100 transmits the coefficient (parameter) of the Ising model of Formula (36) derived by the above transformation processing to the Ising machine 10.

The Ising machine 10 that has acquired the coefficient (parameter) of the Ising model of Formula (36) from the reception device 100 executes calculation and transmits the result to the reception device 100. The Ising machine 10 transmits the calculated (measured) value of the Ising spin to the reception device 100. The Ising machine 10 transmits the calculated (measured) value of each element of σ to the reception device 100.

Using the following Formula (38), the reception device 100 generates (decodes) the message by converting the acquired value of the Ising spin into the value of the message.

$${m}_{j}^{*} = \frac{1}{2} ( 1 - {σ}_{j}^{*} ) \qquad ( 38 )$$

Formula (38) indicates, as an example, an expression of generating a j-th element mⱼ of the message m. The element mⱼ is a value obtained by subtracting the corresponding j-th Ising spin σⱼ from “1” and multiplying the result by ½. For example, when the value of the Ising spin σⱼ is “−1”, the element mⱼ is “1 (=½ (1−(−1))”. For example, when the value of the Ising spin σⱼ is “1”, the element mⱼ is “0 (=½ (1−1))”. In this manner, the reception device 100 can generate a message from the resulting Ising spin. Note that the reception device 100 decodes the message by similarly processing elements other than the j-th element of the message m. With the above processing, the reception device 100 can obtain the optimal message sequence.

### 2-1-6. Summary and Others

In summary, the maximum likelihood decoding by the conversion method according to the first embodiment can be formulated with the Ising model by the following procedure.

For example, removal of mod 2 in the maximum likelihood decoding can be formulated by Formulas (25) to (28). That is, the first transformation of the conversion method is implemented by Formulas (25) to (28).

Furthermore, for example, the expression of the information bits by the spin can be formulated by Formula (30). That is, the second transformation of the conversion method is implemented by Formula (30).

Furthermore, for example, the constraint term associated with the reduction of the spin dimension can be formulated by Formula (33). Furthermore, for example, the formulation of the Ising model using the constraint term can be formulated by Formula (36). That is, the third transformation of the conversion method is implemented by Formulas (33) and (36).

As described above, the reception device 100 obtains the optimal spin arrangement by giving the Ising model to the Ising machine 10, and obtains the information bit from the obtained spin arrangement.

As described above, the communication system 1 uses the maximum likelihood decoding method instead of the SumProduct method. In the communication system 1, the maximum likelihood decoding method can be formulated as a problem of combinatorial optimization of bits constituting a message. Furthermore, in the communication system 1, it is possible to have a configuration (system configuration) so as to solve the problem of combinatorial optimization by a quantum annealer or an equivalent Ising machine.

Furthermore, for example, in a case where the above-described processing is expressed as a program, reduction of a spin dimension, derivation of a constraint term, and formulation of an Ising model using the constraint term can be described as a program.

For example, the spin and constraint terms for dimension reduction such as Formulas (32), (32-2), (32-3), (32-4), (34), and (35) can be derived by the following program.

def product_to_constraint(sigma):

mi=len(sigma)

sigma_ps=[ ]

penalties=[ ]

sigma_ps.append(sigma[0])

penalties.append(0)

for k in range(mi−1):
sigma_k=sigma[k+1]
sigma_q=sigma_ps[−1]
sigma_p=sigma_q*sigma_k
penalty=3*sigma_p+sigma_q*sigma_k−2*sigma_p*(sigma_q+sigma_k)
sigma_ps.append(sigma_p)
penalty.append(penalty)

return sigma_ps[1:], penalties[1:]

The following description corresponds to the above program.

def product_to_constraint(sigma):

mi=len(sigma)

sigma_ps=[ ]

penalties=[ ]

sigma_ps.append(sigma[0])

penalties.append(0)

for k in range(mi−1):

sigma_k=sigma[k+1]

sigma_q=sigma_ps[−1]

sigma_p=sigma_q*sigma_k

penalty=3*sigma_p+sigma_q sigma_k−2*sigma_p*(sigma_q+sigma_k)

sigma_ps.append(sigma_p)

penalty.append(penalty)

return sigma_ps[1:], penalties[1:]

Here, the input sigma is an array of variables representing spin, and the variable representing spin is a variable having a predetermined type (class) on the program. Furthermore, sigma_ps of the output is an array of variables representing an auxiliary spin, and is an array of variables of the same type (class) as sigma. On the other hand, the penalties of the output are arrays representing constraints of sigma and sigma_p, and have the same type as the objective function. The type (class) of the objective function is a class having, as parameters, serial numbers and pointers of sigma variables of all spins constituting the objective function, and linear coefficient of all spins and quadratic coefficient between all spins. When a variable transformed from the original objective function into a quadratic or lower form using the auxiliary spin is h_ising, an objective function obtained by sequentially adding constraints of the auxiliary spin is expressed as follows.

h=h_ising

for penalty in penalties: h+=lambda*penalty

Here, lambda is a parameter of an undetermined constant constraint. In this manner, by adding penalties to h_ising, sigma and the parameter are updated. By extracting the linear and quadratic coefficients from the finally obtained objective function variable h via an accessors prepared in the objective function class, it i possible to extract the parameters of the Ising model.

### 2-2. Configuration of Reception Device According to First Embodiment

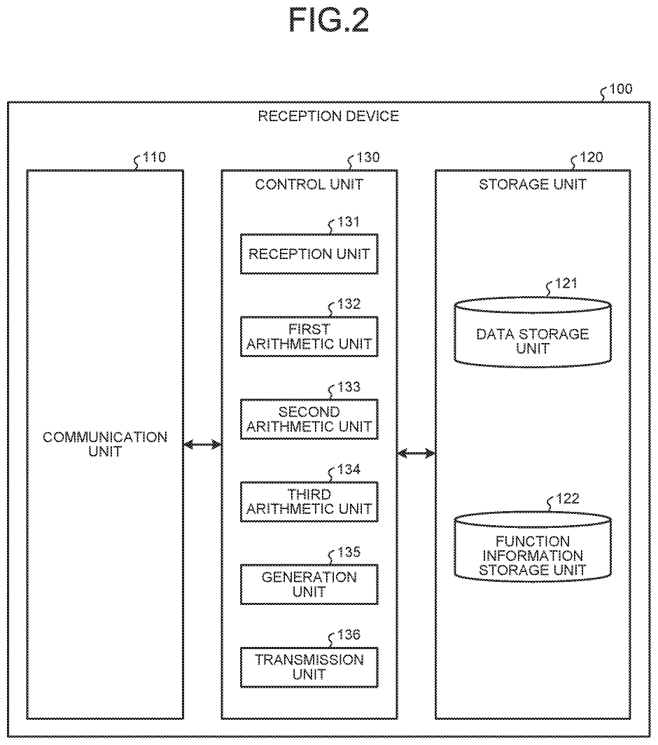

Next, a configuration of the reception device 100, which is an example of a conversion device that executes the processing according to the first embodiment, will be described. FIG. 2 is a diagram illustrating a configuration example of a reception device according to the first embodiment of the present disclosure.

As illustrated in FIG. 2, the reception device 100 includes a communication unit 110, a storage unit 120, and a control unit 130. The reception device 100 may include an input unit (for example, a keyboard, a mouse, etc.) that receives various operations from an administrator or the like of the reception device 100, and a display unit (for example, a liquid crystal display, etc.) for displaying various types of information.

The communication unit 110 is actualized by a network interface card (NIC), for example. The communication unit 110 is connected to a predetermined network (not illustrated) in a wired or wireless manner, and transmits and receives information to and from other information processing devices such as the Ising machine 10 and the transmission device 50. Furthermore, the communication unit 110 may transmit and receive information to and from a user terminal (not illustrated) used by the user.

The storage unit 120 is implemented by semiconductor memory elements such as random access memory (RAM) and flash memory, or other storage devices such as a hard disk or an optical disc. As illustrated in FIG. 2, the storage unit 120 according to the first embodiment includes a data storage unit 121 and a function information storage unit 122.

Although not illustrated, the data storage unit 121 stores various data. The data storage unit 121 stores various data such as data received from another device and decoded data. Although not illustrated, the function information storage unit 122 stores information of various functions. For example, the function information storage unit 122 stores information of various functions used for the conversion processing and the generation processing. For example, the function information storage unit 122 stores information of a function used for processing among the above-described Formulas (1) to (38). Note that the storage unit 120 is not limited to the above, and may store various types of information depending on the purpose. For example, the storage unit 120 may store the program represented by Mathematical Expression 39 described above.

The control unit 130 is actualized by execution of programs stored in the reception device 100 (for example, conversion processing program according to the present disclosure, etc.) by a central processing unit (CPU), a micro processing unit (MPU), or the like, using random access memory (RAM) or the like, as a working area. Furthermore, the control unit 130 is actualized by, for example, an integrated circuit such as an application specific integrated circuit (ASIC) or a field programmable gate array (FPGA).

As illustrated in FIG. 2, the control unit 130 includes a reception unit 131, a first arithmetic unit 132, a second arithmetic unit 133, a third arithmetic unit 134, a generation unit 135, and a transmission unit 136, and implements or executes a function and an action of information processing described below. The internal configuration of the control unit 130 is not limited to the configuration illustrated in FIG. 2, and may be another configuration as long as it is a configuration that performs information processing described below. Furthermore, the connection relationship of the processing units included in the control unit 130 is not limited to the connection relationship illustrated in FIG. 2, and may be a different connection relationship.

The reception unit 131 receives various types of information. The reception unit 131 receives various types of information from an external information processing device. The reception unit 131 receives various types of information from the Ising machine 10. The reception unit 131 receives various types of information from another information processing device such as the transmission device 50.

The reception unit 131 acquires various types of information from the storage unit 120. The reception unit 131 acquires various types of information from the data storage unit 121 and the function information storage unit 122. The reception unit 131 receives a codeword including a message encoded by encoding from the transmission device 50.

In the example of FIG. 1, the reception unit 131 receives the codeword CT′ corresponding to the codeword CT. The reception unit 131 receives the codeword CT′ produced as a result of channel noise mixed in the codeword CT.

The first arithmetic unit 132 executes various types of arithmetic processing. The first arithmetic unit 132 executes processing related to conversion of the objective function into the form of the Ising model. The first arithmetic unit 132 executes a first transformation. The first arithmetic unit 132 executes arithmetic processing using information stored in the data storage unit 121 or the function information storage unit 122. The first arithmetic unit 132 executes the first transformation using the information of the function stored in the function information storage unit 122. The first arithmetic unit 132 executes the first transformation on the information received by the reception unit 131.

The first arithmetic unit 132 removes the modulo 2 operation from the objective function by the first transformation. In the example of FIG. 1, the first arithmetic unit 132 converts the form of the objective function from Formula (18) into Formula (28) by using the first transformation to remove the mod 2 operation.

The second arithmetic unit 133 executes various types of arithmetic processing. The second arithmetic unit 133 executes processing related to conversion of the objective function into the form of the Ising model. The second arithmetic unit 133 executes the second transformation. The second arithmetic unit 133 executes arithmetic processing using the information stored in the data storage unit 121 or the function information storage unit 122. The second arithmetic unit 133 executes the second transformation using the information of the function stored in the function information storage unit 122. The second arithmetic unit 133 executes the second transformation on the objective function on which the first transformation has been executed by the first arithmetic unit 132.

Using the second transformation, the second arithmetic unit 133 replaces the first variable corresponding to the target included in the objective function with the second variable corresponding to the Ising spin. The second arithmetic unit 133 executes second transformation of replacing the first variable corresponding to the target included in the objective function with the second variable corresponding to the Ising spin. The second arithmetic unit 133 replaces the first variable to be optimized included in the objective function with the second variable corresponding to the Ising spin.

In the example of FIG. 1, the second arithmetic unit 133 converts the form of the objective function from Formula (28) into Formula (30) by using the second transformation, and replaces the first variable corresponding to the target with the second variable corresponding to the Ising spin.

The third arithmetic unit 134 executes various types of arithmetic processing. The third arithmetic unit 134 executes processing related to conversion of the objective function into the form of the Ising model. The third arithmetic unit 134 executes the third transformation. The third arithmetic unit 134 executes arithmetic processing using the information stored in the data storage unit 121 or the function information storage unit 122. The third arithmetic unit 134 executes the third transformation using the information of the function stored in the function information storage unit 122. The third arithmetic unit 134 executes the third transformation on the objective function on which the second transformation has been executed by the second arithmetic unit 133. The third arithmetic unit 134 reduces the degree of the second variable related to the objective function.

The third arithmetic unit 134 reduces the degree of the second variable by using the third transformation. The third arithmetic unit 134 executes a third transformation of adding a constraint term to the objective function according to the reduction of the degree of the second variable. The third arithmetic unit 134 converts the objective function into the form of the Ising model by using the third transformation that reduces the degree of the second variable of the objective function to the second degree or less. The third arithmetic unit 134 converts the objective function into the form of the Ising model by using the third transformation that reduces the degree of the second variable to the second degree. The third arithmetic unit 134 adds the second variable according to the reduction of the degree of the second variable, and adds a constraint term related to the second variable added to the objective function.

In the example of FIG. 1, the third arithmetic unit 134 reduces the degree of the second variable “σ” by using the third transformation. The third arithmetic unit 134 transforms the form of the objective function from Formula (30) to Formula (36).

The generation unit 135 generates various types of information. The generation unit 135 generates various types of information based on information from an external information processing device or information stored in the storage unit 120. The generation unit 135 generates various types of information based on information from other information processing devices such as the Ising machine 10 and the transmission device 50. The generation unit 135 generates various types of information based on the information stored in the data storage unit 121 or the function information storage unit 122.

The generation unit 135 generates various types of information based on the various types of information acquired by the reception unit 131. The generation unit 135 executes decoding processing using the calculation result of the Ising machine 10 acquired from the Ising machine 10, and generates decoded information.

The generation unit 135 generates information in which the codeword received by the reception unit 131 has been decoded, by using a value of an Ising spin calculated based on an objective function converted into a form of an Ising model and using a function that converts the Ising spin into a message, the objective function having been converted into the form of the Ising model by removing a modulo 2 operation from a target objective function related to decoding in the coding, replacing the first variable corresponding to the target included in the objective function with a second variable corresponding to the Ising spin, and reducing the degree of the second variable.

In the example of FIG. 1, the generation unit 135 generates (decodes) the message by converting the acquired value of the Ising spin into a value of the message using Formula (38).

The transmission unit 136 provides various types of information to an external information processing device. The transmission unit 136 transmits various types of information to an external information processing device. For example, the transmission unit 136 transmits various types of information to other information processing devices such as the Ising machine 10 and the transmission device 50. The transmission unit 136 provides the information stored in the storage unit 120. The transmission unit 136 transmits the information stored in the storage unit 120.

The transmission unit 136 provides various types of information based on information from other information processing devices such as the Ising machine 10 and the transmission device 50. The transmission unit 136 provides various types of information based on the information stored in the storage unit 120. The transmission unit 136 provides various types of information based on the information stored in the data storage unit 121 or the function information storage unit 122.

### 2-3. Configuration of Ising Machine

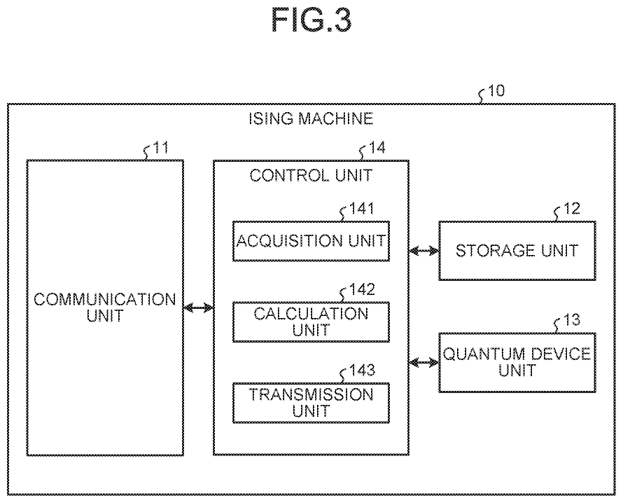

Next, a configuration of the Ising machine 10 that executes calculation will be described. FIG. 3 is a diagram illustrating a configuration example of the Ising machine.

As illustrated in FIG. 3, the Ising machine 10 includes a communication unit 11, a storage unit 12, a quantum device unit 13, and a control unit 14. Note that, the Ising machine 10 may include an input unit (for example, a keyboard, a mouse, etc.) that receives various operations from an administrator or the like of the Ising machine 10, and a display unit (for example, a liquid crystal display, etc.) for displaying various types of information.

The communication unit 11 is implemented by, for example, an NIC, a communication circuit, or the like. The communication unit 11 is connected to a predetermined network (the Internet, or the like) in a wired or wireless manner, and transmits and receives information to and from another device such as the reception device 100 via the network.

The storage unit 12 is implemented by a semiconductor memory element such as RAM or flash memory, or a storage device such as a hard disk or an optical disk, for example. The storage unit 12 stores various types of information used for displaying information.

The quantum device unit 13 executes various quantum calculations. For example, the quantum device unit 13 is implemented by a quantum processing unit (QPU). The quantum device unit 13 implements the ground state of the Ising model based on the parameter of the Ising model received from another device such as the reception device 100, for example. In other words, the quantum device unit 13 implements the optimal spin arrangement in which the Ising model is in the ground energy state. That is, the quantum device unit 13 implements a state in which the optimization problem is optimized.

The quantum device unit 13 includes a plurality of quantum bits, for example. The quantum device unit 13 is pre-cooled to near absolute zero. After the parameters of the Ising model are input to the quantum device unit 13, the quantum device unit 13 applies time evolution on the ratio between the Ising model and the transverse model (quantum fluctuation model). With this operation, optimal spin arrangement according to the parameters of the Ising model is implemented on the quantum device unit 13. In this manner, the optimal spin arrangement of the Ising model is physically implemented on the quantum device unit 13. By measurement of the quantum device unit 13, the optimal spin arrangement of the Ising model can be obtained. With this operation, the quantum device unit 13 can optimize the discrete optimization problem. For example, the quantum device unit 13 can optimize an optimization problem of an objective function of a binary quadratic form.

The control unit 14 is implemented by execution of a program stored in the Ising machine 10 by the CPU, MPU, or the like, with RAM or the like used as a working area. Furthermore, the control unit 14 may be a controller and may be implemented by using an integrated circuit such as an ASIC or an FPGA, for example.

As illustrated in FIG. 3, the control unit 14 includes an acquisition unit 141, a calculation unit 142, and a transmission unit 143, and implements or executes a function and an action of information processing described below. The internal configuration of the control unit 14 is not limited to the configuration illustrated in FIG. 3, and may be another configuration as long as it is a configuration that performs information processing described below.

The acquisition unit 141 receives various types of information. The acquisition unit 141 receives various types of information from an external information processing device. The acquisition unit 141 receives various types of information from another information processing device such as the reception device 100.

The acquisition unit 141 performs calculation using the quantum device unit 13, for example, and receives an instruction for measurement from another information processing device such as the reception device 100. The acquisition unit 141 receives parameters of the Ising model as an instruction of calculation (measurement) by the quantum device unit 13.

The acquisition unit 141 acquires various types of information. The acquisition unit 141 acquires various types of information from the storage unit 12. The acquisition unit 141 acquires various types of information from an external information processing device such as the reception device 100. The acquisition unit 141 acquires the input information received by the input unit. The acquisition unit 141 acquires, for example, information regarding a parameter of the Ising model from an external information processing device. The acquisition unit 141 acquires a measurement result (calculation result) of the quantum device unit 13 by the calculation unit 142.

In the example of FIG. 1, the acquisition unit 141 receives the coefficient (parameter) of the Ising model of the above Formula (36) from the reception device 100.

The calculation unit 142 executes various calculations. The calculation unit 142 executes calculation using the quantum device unit 13. The calculation unit 142 measures the quantum device unit 13. The calculation unit 142 measures the quantum device unit 13 in which the optimal spin arrangement of the Ising model is implemented.

In the example of FIG. 1, the calculation unit 142 executes calculation using coefficients (parameters) of the Ising model of Formula (36).

The transmission unit 143 transmits various types of information to an external information processing device. For example, the transmission unit 143 transmits various types of information to another information processing device such as the reception device 100. The transmission unit 143 transmits the information stored in the storage unit 12.

The transmission unit 143 transmits various types of information based on information from another information processing device such as the reception device 100. The transmission unit 143 transmits various types of information based on the information stored in the storage unit 12.

The transmission unit 143 transmits the measurement result of the quantum device unit 13 obtained by the calculation unit 142 to the device that has instructed the calculation. The transmission unit 143 transmits the measurement result of the quantum device unit 13 obtained by the calculation unit 142 to the transmission source of the parameter. The transmission unit 143 transmits the measurement result of the quantum device unit 13 by the calculation unit 142 to the calculation request source. The transmission unit 143 transmits the measurement result of the quantum device unit 13 obtained by the calculation unit 142 to another information processing device such as the reception device 100.

In the example of FIG. 1, the transmission unit 143 transmits the value of the Ising spin calculated (measured) using the parameter received from the reception device 100 to the reception device 100. The transmission unit 143 transmits the calculated (measured) value of each element of σ (second variable) to the reception device 100.

### 2-4. Procedure of Information Processing According to First Embodiment

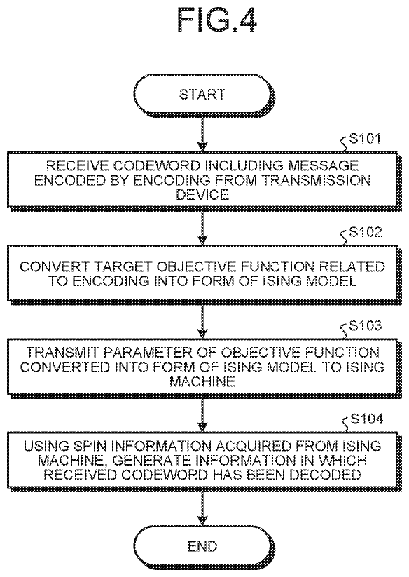

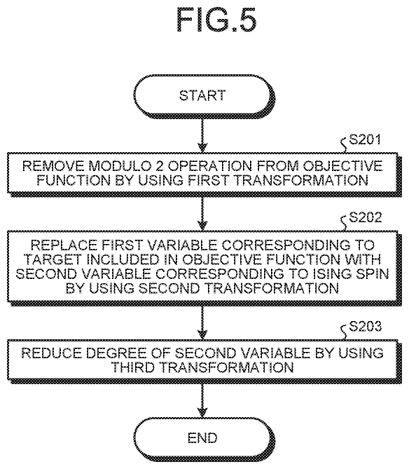

Next, a procedure of various types of processing according to the first embodiment will be described with reference to FIGS. 4 and 5.

### 2-4-1. Procedure of Decoding Processing Related to Communication System

First, a flow of information processing according to the first embodiment of the present disclosure will be described with reference to FIG. 4. FIG. 4 is a flowchart illustrating a procedure of decoding processing by the communication system.

As illustrated in FIG. 4, the reception device 100 receives a codeword including a message encoded by encoding from the transmission device (step S101). The reception device 100 converts the target objective function related to encoding into the form of the Ising model (step S102). The reception device 100 transmits the parameter of the objective function converted into the form of the Ising model to the Ising machine 10 (step S103). Using spin information acquired from the Ising machine 10, the reception device 100 generates information in which the received codeword has been decoded (step S104).

### 2-4-2. Procedure of Conversion Processing Related to Reception Device

Next, a flow of information processing according to the first embodiment of the present disclosure will be described with reference to FIG. 5. FIG. 5 is a flowchart illustrating a procedure of conversion processing performed by the reception device.

As illustrated in FIG. 5, the reception device 100 removes a modulo 2 operation from the objective function by using the first transformation (step S201). By using the second transformation, the reception device 100 replaces the first variable corresponding to the target included in the objective function with the second variable corresponding to the Ising spin (step S202). The reception device 100 reduces the degree of the second variable by using the third transformation (step S203).

### 2-5. Example of Configuration of Communication System

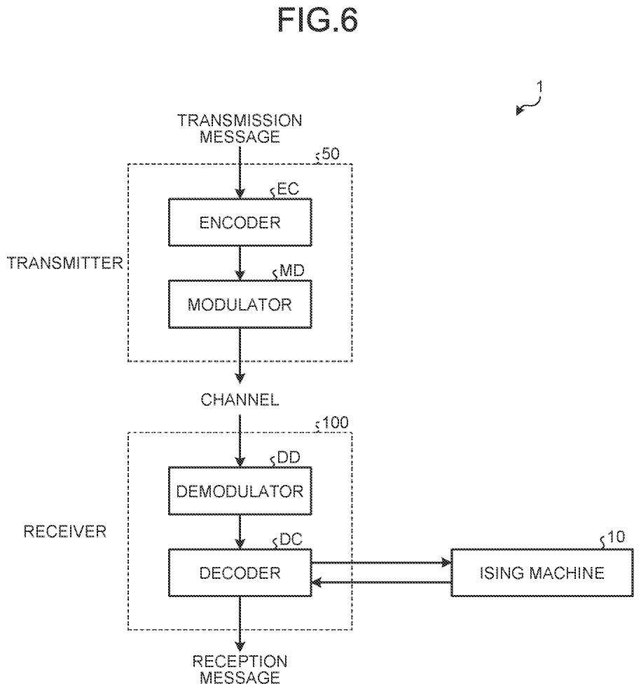

Here, a configuration of the communication system illustrated in FIG. 6 will be described. FIG. 6 is a diagram illustrating an example of a configuration of a communication system.

In the communication system 1 illustrated in FIG. 6, the transmission device 50 which is a transmission-side device (transmitter) has a configuration including an encoder EC and a modulator MD. The transmission device 50 transmits, via a channel, information (signal) obtained by converting a transmission message using the encoder EC or the modulator MD to the reception device 100 which is a reception-side device (receiver). The reception device 100 has a configuration including a demodulator DD and a decoder DC, converts received information (reception signal) using the demodulator DD or and decoder DC so as to decode the transmission message. The communication system 1 illustrated in FIG. 6 is different from the above-described conventional communication system in that the Ising machine 10 is included.

For example, the transmission message is a bit sequence of information to be transmitted from the transmission device 50 to the reception device 100. The transmission device 50 includes an encoder EC that converts a transmission message into a bit string of a more redundant channel code. The transmission device 50 includes a modulator MD that converts a channel code into a signal suitable for the channel. The modulator MD plays a role of superimposing a signal of the channel code over a carrier wave, for example. Since the processing performed by the modulator MD is similar to that of the conventional modulator, the description thereof will be omitted. The channel is a medium that transmits a signal. Regarding the signal transmitted over the channel, the quality of the signal might deteriorate due to addition of noise or distortion of the signal during transmission.

The reception device 100 includes a demodulator DD that converts a signal on a carrier wave into a signal of a channel code. Since the processing performed by the demodulator DD is similar to that of the conventional demodulator, the description thereof will be omitted. The reception device 100 includes a decoder DC that reproduces a transmission message from a reception signal corresponding to a redundant channel code. As described above, by causing the Ising machine 10 to perform calculation, the reception device 100 (specifically, the decoder DC thereof) acquires the value of the Ising spin and decodes the message using the acquired value of the Ising spin.

### 2-5-1. Procedure of Decoding Processing Related to Communication System

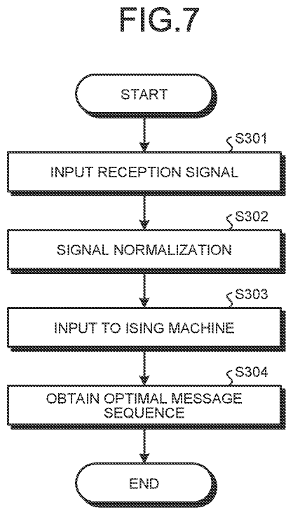

Next, a flow of decoding processing related to the communication system will be described with reference to FIG. 7. FIG. 7 is a flowchart illustrating a procedure of decoding processing performed by the communication system.

As illustrated in FIG. 7, reception device 100 receives an input of a reception signal (step S301). Subsequently, the reception device 100 performs signal normalization (step S302). Here, the signal normalization is processing of regulating the amplitude of a reception signal r to be kept within a range from “0” to “1”. However, this amplitude value is not very important in practice. The point is that, when the signal is obtained as a result of subtraction of ½ from the reception signal r, that is, when the signal is “r−½”, the signal bias is correctly removed, and the positive and negative signs are appropriate. This can be implemented by using processing of detecting offset information by smoothing a signal with an infinite impulse response (IIR) filter or the like and performing a feedback of the obtained offset information to the signal so as to remove the offset information.

Subsequently, the reception device 100 performs input to the Ising machine (step S303). For example, the reception device 100 inputs a parameter or the like of the objective function converted into the form of the Ising model to the Ising machine. The input to the Ising machine includes an input of the above-described objective function and a parameter of an energy function in a quadratic form calculated by a constraint term by degree reduction. This input is performed via communication in a case where the Ising machine 10 is used on the server side, for example, in a cloud format. In addition, when the Ising machine 10 can be used on the edge side, parameters may be directly input to the Ising machine 10.

Subsequently, the reception device 100 obtains an optimal message sequence (step S304). For example, the reception device 100 can obtain the optimal message sequence using the above Formula (38). Here, the output from the Ising machine 10 is the spin corresponding to the bit string of the message and the spin of the degree reduction. Since these pieces of information can be obtained separately, the bit string is obtained from the spin corresponding to the bit string of the message.

### 3. SECOND EMBODIMENT

Although the above-described example is the case where the Ising spin is converted into the message and the message is generated from the Ising spin, the information generated from the Ising spin is not limited to the above, and may be various information. For example, the Ising spin may be converted into a codeword, and the codeword may be generated from the Ising spin. This point will be described below. The communication system 1 according to a second embodiment includes a reception device 100A instead of the reception device 100. Note that description of points similar to the reception device 100 of the first embodiment will be omitted as appropriate.

### 3-1. Conversion Processing According to Second Embodiment

Hereinafter, the conversion processing according to the second embodiment will be described. Note that description of points similar to the conversion processing of the first embodiment will be omitted as appropriate.

### 3-1-1. Formulation of Maximum Likelihood Decoding

In the second embodiment, conversion processing (formulation) using a parity check matrix instead of a generator matrix is performed. Specifically, the processing uses the following Formula (40) obtained by adding a constraint of a parity check matrix as a constraint term to the maximum likelihood decoding of the above Formula (17).

$${x}^{*} = {arg min}_{x} ( {\sum }_{i = 1}^{N} {( {r}_{i} - {x}_{i} )}^{2} + λ {\sum }_{k = 1}^{K} ( ( {\sum }_{i = 1}^{N} {h}_{k i} {x}_{i} ) mod 2 ) ) \qquad ( 40 )$$

Here, in the objective function of optimization expressed in Formula (40), the first term on the right side represents maximum likelihood decoding, and the second term on the right side is a constraint term by the parity check matrix. hₖᵢ is an element (ki component) of k rows and i columns of the parity check matrix expressed by the above Formula (4). λ is a positive parameter. Although the parameter λ can be set to an independent parameter for each parity check bit, here, the parameter λ is set to an identical parameter. Formula (40) is not equivalent to Formula (17). However, when x satisfies the condition of the parity check and this makes the second term “0”, the same optimization as in Formula (17) can be obtained.

Therefore, the parameter λ is set to a large value, for example, a value of “6” or more, so as to preferentially optimize the second term. Alternatively, following the Lagrange multiplier, the parameter λ is increased by the gradient method as in the Formula (41) below until the constraint term becomes “0”.

$$λ ← λ + γ {\sum }_{k = 1}^{K} ( ( {\sum }_{i = 1}^{N} {h}_{ki} {x}_{i} ) mod 2 ) \qquad ( 41 )$$

Here, γ is a small positive value and is an update parameter of the gradient method. In this manner, the optimization solution of Formula (40) can be made the same solution as the optimization of Formula (17).

Therefore, the reception device 100A performs the transformation processing including the first to third transformations as described below on Formula (40) being the objective function so as to remove mod 2 and convert the objective function into the form of the Ising model.

### 3-1-2. First Transformation (Removal of Mod 2 Operation)

First, the reception device 100A removes the mod 2 operation by using the first transformation. The objective function of the optimization of Formula (40) includes a modulo 2 (mod 2) operation. Therefore, the reception device 100A removes the mod 2 operation using the above Formula (19). With this procedure, a portion other than the parameter λ of the second term on the right side of Formula (40) can be converted into Formula (42) as below.

$${\sum }_{k = 1}^{K} ( ( {\sum }_{i = 1}^{N} {h}_{ki} {x}_{i} ) mod 2 ) = \frac{1}{2} {\sum }_{k = 1}^{K} ( 1 - {\prod }_{i = 1}^{N} ( 1 - 2 * {h}_{ki} {x}_{i} ) ) \qquad ( 42 )$$

In this manner, the right side of Formula (42) does not include the mod 2 operation. The reception device 100A removes a mod 2 operation by converting a portion other than the parameter λ of the second term of the right side of Formula (40) into the right side of Formula (42).

### 3-1-3. Second Transformation (Replacement with Ising Spin)

Next, the reception device 100A performs replacement with an Ising spin by using the second transformation. The reception device 100A performs replacement with the Ising spin by using the conversion equation “σᵢ=1−2xᵢ”. For example, the reception device 100A replaces the first variable “x” corresponding to the codeword with the second variable “σ” corresponding to the Ising spin. The reception device 100A transforms Formula (40) into Formula (43) below by using the conversion equation “σᵢ=1−2xᵢ”. For example, using the conversion equation “σᵢ=1−2xᵢ”, the reception device 100A transforms an equation obtained by converting a portion other than the parameter λ of the second term on the right side of the Formula (40) into the right side of the Formula (42) into the following Formula (43).

$${σ}^{*} = {arg min}_{σ} ( {\sum }_{i = 1}^{N} {( {r}_{i} - \frac{1 - {σ}_{i}}{2} )}^{2} + \frac{λ}{2} {\sum }_{k = 1}^{K} ( 1 - {\prod }_{i = 1}^{N} ( 1 - {h}_{ki} + {h}_{ki} {σ}_{i} ) ) ) \qquad ( 43 )$$

Formula (43) is rearranged to obtain the following Formula (44).

$${σ}^{*} = {arg min}_{σ} ( {\sum }_{i = 1}^{N} ( {r}_{i} - \frac{1}{2} ) {σ}_{i} + \frac{λ}{2} ( K - {\sum }_{k = 1}^{K} {\prod }_{m = 1}^{{N}_{k}} {σ}_{{k}_{m}} ) ) \qquad ( 44 )$$

Here, Nₖ is the number of “1” in k rows of the check matrix. In addition, kₘ is an index number of a column in which “1” appears m-th from the left in k rows of the check matrix.

In this manner, in Formula (44), the first variable “xᵢ” corresponding to the codeword has been replaced with the second variable “σᵢ” corresponding to the Ising spin. The reception device 100A converts the form of the objective function from Formula (40) to Formula (44) by the second transformation, and replaces the first variable corresponding to the target with the second variable corresponding to the Ising spin.

### 3-1-4. Third Transformation (Degree Reduction)

This combinatorial optimization has Nₖ-dimensions regarding σ, but can be reduced to two dimensions by the method of dimension reduction illustrated in the first embodiment. For example, new spins σₚₘ (m=2 . . . Nₖ) are sequentially introduced as in the following Formulas (45), (45-2), (45-3), and (45-4) for the term of the product of the dimension of Nₖ regarding the kth check bit so as to reduce the dimension of the product.

$${\prod }_{m = 1}^{{N}_{k}} {σ}_{{k}_{m}} = {σ}_{{k}_{1}} {σ}_{{k}_{2}} {σ}_{{k}_{3}} … {σ}_{{N}_{k}} \qquad ( 45 )$$

$$= {σ}_{{p}_{2}} {σ}_{{k}_{3}} … {σ}_{{N}_{k}} , ( {σ}_{{p}_{2}} = {σ}_{{k}_{1}} {σ}_{{k}_{2}} ) \qquad ( 45 - 2 )$$

$$= {σ}_{{p}_{m}} {σ}_{{k}_{m + 1}} … {σ}_{{N}_{k}} , ( {σ}_{{p}_{m}} = {σ}_{{p}_{m - 1}} {σ}_{{k}_{m}} ) \qquad ( 45 - 3 )$$

$$= {σ}_{{p}_{{N}_{k}}} ( {σ}_{{p}_{{N}_{k}}} = {σ}_{{p}_{{N}_{k} - 1}} {σ}_{{k}_{{N}_{k}}} ) \qquad ( 45 - 4 )$$

Formula (45-2) represents a case where the degree is reduced by 1 from Formula (45). Specifically, Formula (345-2) represents a case where the degree of the second variable “σ” is reduced by 1 from Formula (45) by defining the product of σₖ₁ and σₖ₂ as σₚ₂. In this manner, the dimension of the optimization formula (44) can be reduced to one dimension as expressed in the following Formula (46).

$${σ}^{*} = {arg min}_{σ} ( {\sum }_{i = 1}^{N} ( {r}_{i} - \frac{1}{2} ) {σ}_{i} + \frac{λ}{2} ( K - {\sum }_{k = 1}^{K} {σ}_{{p}_{{N}_{k}}} ) ) \qquad ( 46 )$$

Note that the newly introduced spins satisfy the constraints of quadratic expressions as expressed in the following Formulas (47) and (48) similar to the above Formula (31).

H_{k,2}=3σₚ_{₂}+σᵢ_{₁}σᵢ_{₂}−2σᵢ_{₁}σₚ_{₂}−2σᵢ_{₂}σₚ_{₂} (47)

Hₖₘ=3σₚ_{ₘ}+σₚ_{ₘ₋₁}σₖ_{ₘ}−2σₚ_{ₘ₋₁}σₚ_{ₘ}−2σₖ_{ₘ}σₚ_{ₘ} (35)

When the optimization Formula (44) is transformed into a form of a Lagrange multiplier so as to satisfy this constraint, the following Formula (49) is obtained.

$${σ}^{*} , {σ}_{p}^{*} = {arg min}_{σ , {σ}_{p}} ( {\sum }_{i = 1}^{N} ( {r}_{i} - \frac{1}{2} ) {σ}_{i} + \frac{λ}{2} ( K - {\sum }_{k = 1}^{K} ( {σ}_{{p}_{{N}_{k}}} + {\sum }_{m = 2}^{{N}_{k}} {H}_{km} ) ) ) \qquad ( 49 )$$

Here, since all the constraint expressions has only values of “0” or more, a case where the same multiplier λ is used will be described. Formula (49) includes the term of the second degree or less regarding spin and can be optimized with an Ising machine. In this manner, the reception device 100A transforms the Formula (40) of the objective function of the maximum likelihood decoding into the form of the Ising model, that is, Formula (49) corresponding to the Hamiltonian of the Ising model. Incidentally, in order to reliably satisfy the constraint of the parity check, the parameter λ may be updated as in the following Formula (50).

$$λ ← λ + γ ( K - {\sum }_{k = 1}^{K} ( {σ}_{{p}_{{N}_{k}}} + {\sum }_{m = 2}^{{N}_{k}} {H}_{km} ) ) \qquad ( 50 )$$

Since the constraint of the parity check is satisfied at a point where the second term becomes “0”, the update of the parameter λ is ended. As described above, it is possible to derive an energy function (Hamiltonian) of the Ising model equivalent to the objective function of the maximum likelihood decoding.

### 3-1-5. Optimization

Thereafter, in the optimization, the coefficients (parameters) of spins of the first and second degrees of the Ising model are calculated through a computer program or the like. For example, the reception device 100A calculates the coefficients (parameters) of the spins in the first and second degrees of Formula (49).

Next, the obtained coefficients (parameters) are given to the Ising machine 10 so as to perform parameter settings necessary for calculation of annealing. For example, the reception device 100A transmits the coefficient (parameter) of the Ising model of Formula (49) derived by the above transformation processing to the Ising machine 10.

After completion of the parameter settings, the Ising machine 10 performs annealing processing. Subsequently, the arrangement of spins after annealing is processed again by a computer program to obtain a bit string of a codeword.

For example, after having acquired the coefficient (parameter) of the Ising model of Formula (49) from the reception device 100A, the Ising machine 10 executes calculation and transmits the result to the reception device 100A. The Ising machine 10 transmits the calculated (measured) value of the Ising spin to the reception device 100A. The Ising machine 10 transmits the calculated (measured) value of each element of σ to the reception device 100A.

Thereafter, the reception device 100A restores the codeword by converting the acquired value of the Ising spin into the value of the codeword using the following Formula (51).

$${x}_{i}^{*} = \frac{1}{2} ( 1 - {σ}_{l}^{*} ) \qquad ( 51 )$$

Formula (51) is an example of an expression of generating an i-th element xᵢ of the codeword x. The element xᵢ is a value obtained by subtracting the corresponding i-th Ising spin σᵢ from “1” and multiplying the result by ½. For example, when the value of the Ising spin σᵢ is “−1”, the element xᵢ is “1 (=½(1−(−1)))”. For example, when the value of the Ising spin σᵢ is “1”, the element xᵢ is“0 (=½(1−1))”. In this manner, the reception device 100A can restore the codeword from the Ising spin obtained as a result. Furthermore, the reception device 100A decodes the codeword by similarly processing other elements other than the i-th element of the codeword x.

In the case that the coding is constructed with the systematic code, the reception device 100A can use the code string extracted by the message length from the head of the codeword of Formula (51) that has undergone maximum likelihood decoding, as a message. With this procedure, the reception device 100A generates (decodes) a message. As described above, the reception device 100A can obtain the optimal message sequence.

### 3-1-6. Summary and Others

To summarize the above, the maximum likelihood decoding according to the second embodiment can be formulated with the Ising model by using the following procedure.

For example, the formulation of the Ising model using the constraint term can be formulated by Formula (40).

For example, removal of mod 2 in the maximum likelihood decoding can be formulated by Formula (42). For example, the first transformation of the conversion method is implemented by Formula (42).

Furthermore, for example, the expression of the information bits by spins can be formulated by Formula (44). That is, the second transformation of the conversion method is implemented by Formula (44).

Furthermore, for example, the constraint term associated with the reduction of the spin dimension can be formulated by Formula (46). That is, the third transformation of the conversion method is implemented by Formula (46).

Furthermore, for example, the reformulation of the Ising model using the additional constraint term can be formulated by Formula (49). That is, the third transformation of the conversion method is implemented by Formula (49).

As described above, by giving the Ising model to the Ising machine 10, the reception device 100A obtains the optimal spin arrangement and then obtains the information bit from the spin arrangement obtained.

Furthermore, for example, in a case where the above-described processing is expressed as a program, similarly to the program expressed by Mathematic Expression 39, reduction of a spin dimension, derivation of a constraint term, and formulation of an Ising model using the constraint term can be described as the program.

### 3-2. Configuration of Reception Device According to Second Embodiment

As described above, the reception device 100A, which is a conversion device, converts the objective function of combinatorial optimization related to encoding and decoding into the form of the Ising model. The reception device 100A converts an objective function of a variable constituting a codeword obtained by encoding a message into a form of the Ising model. The reception device 100A converts the objective function including the constraint term using the variable constituting the codeword corresponding to the check matrix into the form of the Ising model.

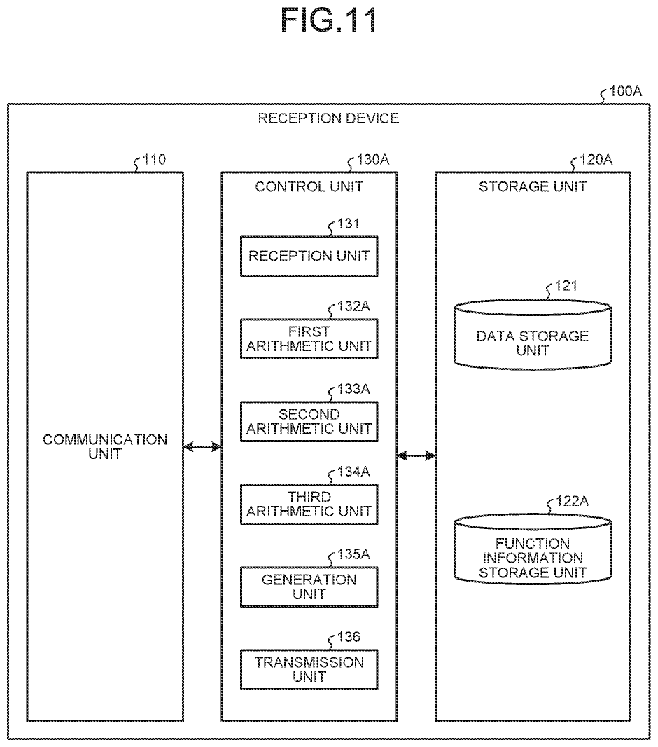

The configuration of the reception device 100A that is an example of a conversion device that executes processing according to the second embodiment will be described. FIG. 11 is a diagram illustrating a configuration example of a reception device according to the second embodiment of the present disclosure.

As illustrated in FIG. 11, the reception device 100A includes a communication unit 110, a storage unit 120A, and a control unit 130A. The reception device 100A may include an input unit (for example, a keyboard, a mouse, etc.) that receives various operations from an administrator or the like of the reception device 100A, and a display unit (for example, a liquid crystal display, etc.) for displaying various types of information.

The storage unit 120A is implemented by a semiconductor memory element such as RAM or flash memory, or a storage device such as a hard disk or an optical disk, for example. As illustrated in FIG. 11, the storage unit 120A according to the second embodiment includes a data storage unit 121 and a function information storage unit 122A.

Although not illustrated, the function information storage unit 122A stores information of various functions. For example, the function information storage unit 122A stores information of various functions used for the conversion processing and the generation processing. For example, the function information storage unit 122A stores information of a function used for processing among the above-described Formulas (1) to (51). Note that the storage unit 120A is not limited to the above, and may store various types of information depending on the purpose.

The control unit 130A is implemented by execution of programs stored in the reception device 100A (for example, a conversion processing program according to the present disclosure) by the CPU, MPU, or the like, using RAM or the like as a working area. Furthermore, the control unit 130A is implemented by an integrated circuit such as ASIC or FPGA.

As illustrated in FIG. 11, the control unit 130A includes a reception unit 131, a first arithmetic unit 132A, a second arithmetic unit 133A, a third arithmetic unit 134A, a generation unit 135A, and a transmission unit 136, and implements or executes a function and an action of information processing described below. The internal configuration of the control unit 130A is not limited to the configuration illustrated in FIG. 11, and may be another configuration as long as it is a configuration that performs information processing described below. Furthermore, the connection relationship of the processing units included in the control unit 130A is not limited to the connection relationship illustrated in FIG. 11, and may be a different connection relationship.

The first arithmetic unit 132A executes various arithmetic processing similarly to the first arithmetic unit 132. By using the first transformation, the first arithmetic unit 132A removes a mod 2 operation by converting a portion other than the parameter λ of the second term of the right side of Formula (40) into the right side of Formula (42).

The second arithmetic unit 133A executes various arithmetic processing similarly to the second arithmetic unit 133. The second arithmetic unit 133A converts the form of the objective function from Formula (40) into Formula (44) by using the second transformation, and replaces the first variable corresponding to the target with the second variable corresponding to the Ising spin.

The third arithmetic unit 134A executes various arithmetic processing similarly to the third arithmetic unit 134. The third arithmetic unit 134A reduces the degree of the second variable “σ” by using the third transformation. The third arithmetic unit 134A transforms the form of the objective function from Formula (44) to Formula (49).

The generation unit 135A generates various types of information similarly to the generation unit 135. Using Formula (51), the generation unit 135A converts the acquired value of the Ising spin into a value of the codeword, thereby generating a codeword. the generation unit 135A extracts the codeword by the message length from the beginning of the codeword generated by Formula (51), thereby restoring the message.

### 4. THIRD EMBODIMENT

### 4-1. Overview of Processing by Communication System According to Third Embodiment of Present Disclosure

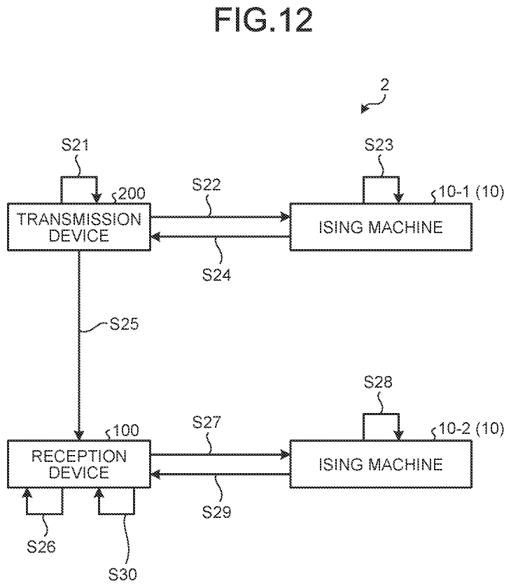

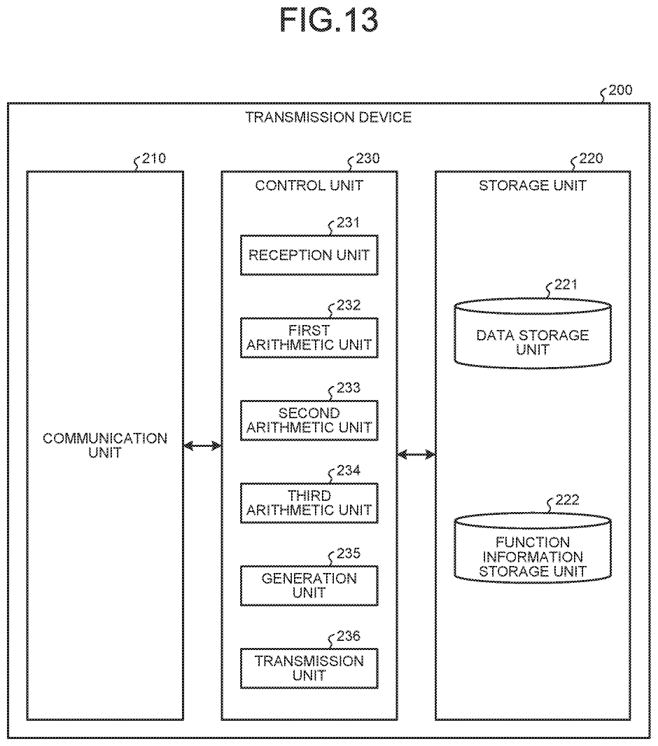

Note that the conversion processing is not limited to the above, and may be performed in encoding. This point will be described with reference to FIGS. 12 to 15. FIG. 12 is a diagram illustrating an example of processing performed by a communication system according to a third embodiment of the present disclosure. The conversion processing according to the third embodiment of the present disclosure is implemented by the transmission device 200 which is an example of the conversion device illustrated in FIG. 13. Note that the transmission device 200 may be a communication device that performs not only the transmission of information but also communication with other devices including transmission/reception of information. In this case, the transmission device 200 also functions as a reception device that transmits information to other devices.

In the description of the third embodiment, description of the points similar to those of the first embodiment and the second embodiment will be appropriately omitted. For example, the processing of the reception device 100 or on the side of the reception device 100 according to the third embodiment is similar to the processing of the reception device 100 or on the side of the reception device 100 and according to the first embodiment, and thus, description of the definition thereof will be omitted.

### 4-1-1. Overview of Configuration of Communication System

First, a configuration of a communication system 2 illustrated in FIG. 12 will be described. FIG. 12 illustrates a configuration example of the communication system 2 according to the third embodiment. As illustrated in FIG. 12, the communication system 2 includes an Ising machine 10-1, an Ising machine 10-2, a transmission device 200, and a reception device 100. The transmission device 200 corresponds to a transmission-side device (transmitter), and the reception device 100 corresponds to a reception-side device (receiver). The example of FIG. 12 illustrates a case where the Ising model is used for encoding information in the transmission device 200 that is transmission-side device (transmitter) and for decoding information in the reception device 100 that is a reception-side device (receiver). The Ising machine 10-1, the Ising machine 10-2, and the like will be referred to as an Ising machine 10 when they are not particularly to be distinguished from each other. Note that the communication system 2 illustrated in FIG. 12 may include three or more Ising machines 10, a plurality of transmission devices 200, and a plurality of reception devices 100.

The transmission device 200 and the reception device 100 are communicably connected by wire or wirelessly via a predetermined network (communication network). The transmission device 200 transmits information (signal) to the reception device 100 via a channel of a predetermined network. In addition, the Ising machine 10 and the reception device 100 are communicably connected to each other by wire or wirelessly via a predetermined network (communication network).

The Ising machine 10 is a computer (calculator) using an Ising model. The Ising machine 10 is a computer that solves a combinatorial optimization problem using an Ising model. In the example of FIG. 12, the Ising machine 10 is a quantum computer (quantum calculator) that solves a problem using quantum annealing. The Ising machine 10 can be implemented by a quantum annealing system or a quantum annealer. Note that the Ising machine 10 is not limited to a computer referred to as a quantum computer, and may be any computer such as an Ising calculator using a complementary metal-oxide-semiconductor (CMOS) or the like, as long as it is a computer using an Ising model. For example, the Ising machine 10 may be an Ising calculator using a processor such as a graphics processing unit (GPU) or using an integrated circuit such as a field programmable gate array (FPGA).

Similarly to the transmission device 50, the transmission device 200 is a transmission-side device (transmitter) that transmits information to another device.

The transmission device 200, which is a conversion device, converts a target objective function related to encoding into a form of an Ising model. The transmission device 200 converts a target objective function related to a code into a form of an Ising model. The transmission device 200 converts an objective function related to channel coding into a form of an Ising model. The transmission device 200 converts an objective function used for encoding into a form of an Ising model.

The transmission device 200 converts an objective function used in processing related to encoding transmitted from the communication device to another communication device into a form of an Ising model. The transmission device 200 converts a target objective function that is a generator matrix used for encoding into a form of an Ising model.

The transmission device 200 instructs the Ising machine 10 to execute calculation. The transmission device 200 transmits the parameters of the Ising model to the Ising machine 10. By transmitting the parameters of the Ising model to the Ising machine 10, the transmission device 200 instructs the Ising machine 10 to execute calculation. The transmission device 200 acquires a calculation result of the Ising machine 10. The transmission device 200 receives a calculation result of the Ising machine 10 from the Ising machine 10. The transmission device 200 generates a generator matrix using the calculation result of the Ising machine 10 acquired from the Ising machine 10.

### 4-1-2. Overview of Processing in Communication System

Here, an overview of processing of the communication system 2 will be described with reference to FIG. 12. The example of FIG. 12 illustrates a case where information (data) is transmitted from the transmission device 200 to the reception device 100, as an example.

The transmission device 200 converts the objective function related to encoding into a form that can be calculated by the Ising machine 10 (step S21). The transmission device 200 performs conversion processing for converting the objective function into the form of the Ising model. The transmission device 200 removes a modulo 2 operation from the target objective function related to coding, replaces a first variable corresponding to the target included in the objective function with a second variable corresponding to an Ising spin, and reduces the degree of the second variable, and thereby converts the objective function into the form of the Ising model. Details of this conversion processing will be described below in [4-1-3. Conversion processing]. In order to simplify the description, the example of FIG. 12 uses a case where the transmission device 200 performs the conversion processing at the timing of transmitting information. However, processing executable before the timing of transmission in the conversion processing may be performed in advance, or may be performed by a conversion device other than the transmission device 200. For example, the first variable is an element constituting a generator matrix used for encoding.

Then, the transmission device 200 instructs the Ising machine 10 to execute calculation by using the information of the objective function after being converted into the form of the Ising model (step S22). The transmission device 200 transmits the parameters of the Ising model to the Ising machine 10. By transmitting the parameter of the objective function after being converted into the form of the Ising model to the Ising machine 10, the transmission device 200 instructs the Ising machine 10 to execute calculation.

After having acquired the parameter from the transmission device 200, the Ising machine 10 executes calculation (step S23). For example, the Ising machine 10 obtains a solution to a combinatorial optimization problem that minimizes an objective function by a technique such as quantum annealing.

Subsequently, the Ising machine 10 transmits the calculation result (measurement result) to the transmission device 200 (step S24). With this operation, the transmission device 200 acquires the calculation result of the Ising machine 10.

The transmission device 200 then generates information using the calculation result of the Ising machine 10 acquired from the Ising machine 10. For example, using the calculation result of the Ising machine 10 acquired from the Ising machine 10, the transmission device 200 generates each element of the generator matrix G to be used for encoding. Subsequently, the transmission device 200 encodes the message (message MX) using the generator matrix G generated. The transmission device 200 generates a codeword (codeword CT) obtained by encoding the message MX.

The transmission device 200 transmits the codeword CT to the reception device 100 via the channel (step S25). Note that processing in steps S26 to S30 on the reception device 100 side after step S25 is similar to the processing in steps S3 to S7 in FIG. 1, and thus description thereof is omitted.

As described above, the transmission device 200 performs the conversion processing for converting the objective function into the form of the Ising model, thereby converting the objective function into a form that can be calculated by the Ising machine 10. In this manner, the communication system 2 can apply the Ising model to processing related to encoding. This makes it possible for the communication system 2 to perform encoding at high speed by using the Ising machine 10.

### 4-1-3. Conversion Processing

Hereinafter, a conversion method will be described.

### 4-1-3-1. Formulation

For example, in a case where it is no longer necessary to use a parity check matrix as in the first embodiment, encoding can be defined only by a generator matrix.

Furthermore, as described above, the generator matrix is a matrix including only elements of “0” or “1”. The elements “0” or “1” of the generator matrix can be regarded as a combinatorial optimization problem. As the objective function, for example, a variance of the distance between codes to be generated, namely, an inter-code distance, as well as a mean, a minimum distance, or a bounded distance are set.

Here, an inter-code distance D(x,x′) of the codewords x and x′ is expressed by the following Formula (52). Formula (52) can be transformed into Formulas (52-2) to (52-4).

$$D ( x , {x}^{′} ) = {\sum }_{i = 1}^{N} ( ( {x}_{i} - {x}_{i}^{′} ) mod 2 ) \qquad ( 52 )$$

$$= {\sum }_{i = 1}^{N} ( ( ( {\sum }_{j = 1}^{M} {ℊ}_{ij} {m}_{j} ) mod 2 - ( {\sum }_{j = 1}^{M} {ℊ}_{ij} {m}_{j}^{′} ) mod 2 ) mod 2 ) \qquad ( 52 - 2 )$$

$$= {\sum }_{i = 1}^{N} ( ( {\sum }_{j = 1}^{M} {ℊ}_{ij} ( ( {m}_{j} - {m}_{j}^{′} ) mod 2 ) ) mod 2 ) \qquad ( 52 - 3 )$$

$$= {\sum }_{i = 1}^{N} ( ( {\sum }_{j = 1}^{M} {ℊ}_{ij} {d}_{j} ) mod 2 ) \qquad ( 52 - 4 )$$

### 4-1-3-2. First Transformation (Removal of Mod 2 Operation)

Here, d is defined as in the following Formula (53).

dⱼ=(mⱼ−m′ⱼ)mod 2 (53)

dⱼ is “1” only when mⱼ and m′ⱼ are different, and is “0” otherwise. In this manner, since dⱼ takes only “0” or “1”, the above-described Formula (30) that transforms mod 2 to the product is established. That is, the inter-code distance can be calculated as the following Formula (54).

$$D ( x , {x}^{′} ) = \frac{1}{2} {\sum }_{i = 1}^{N} ( 1 - {\prod }_{j = 1}^{M} ( 1 - 2 * {ℊ}_{ij} {d}_{j} ) ) \qquad ( 54 )$$

In this manner, Formula (54) does not include the mod 2 operation. By using the first transformation, the transmission device 200 converts the form of the objective function from Formula (52) into Formula (54), thereby removing the mod 2 operation.

### 4-1-3-3. Second Transformation (Replacement with Ising Spin)

The component of the generator matrix will be replaced with the Ising spin using the conversion equation “σᵢⱼ=1-2gᵢⱼ”. The transmission device 200 transforms Formula (54) into Formula (55) below by using the conversion equation “σᵢⱼ=1−2gᵢⱼ”.

$$D ( x , {x}^{′} ) = \frac{1}{2} {\sum }_{i = 1}^{N} ( 1 - {\prod }_{j = 1}^{M} ( 1 - {d}_{j} + {d}_{j} {σ}_{ij} ) ) \qquad ( 55 )$$

In this manner, in Formula (55), the first variable “gᵢⱼ” corresponding to the generator matrix is replaced with the second variable “σᵢⱼ” corresponding to the Ising spin. The transmission device 200 converts the form of the objective function from Formula (54) into Formula (55) by using the second transformation, and replaces the first variable corresponding to the target with the second variable corresponding to the Ising spin.

### 4-1-3-4. Third Transformation (Degree Reduction)

Since dⱼ has only a value of “0” or “1”, Formula (55) can be transformed into the following Formula (56).

$$D ( x , {x}^{′} ) = \frac{1}{2} {\sum }_{i = 1}^{N} ( 1 - {\prod }_{k = 1}^{M} {σ}_{{ij}_{k}} ) = \frac{1}{2} ( N - {\sum }_{i = 1}^{N} {\prod }_{k = 1}^{{D}_{j}} {σ}_{{ij}_{k}} ) \qquad ( 56 )$$

Here, Dj is the number of components of “1” in dj, and jₖ is an index of a k-th component of “1” in dⱼ. D(x,x′) can be the second degree or more regarding σ, and reduction of this degree is performed similarly to the decoding method in the first embodiment. With this operation, a mean μ and a variance σ² can be calculated as the following Formulas (57) and (58).

$${E}_{d \sim p ( d )} [ D ( x , {x}^{′} ) ] = \frac{1}{2} ( N - {E}_{d \sim p ( d )} [ {\sum }_{i = 1}^{N} {\prod }_{k = 1}^{{D}_{j}} {σ}_{{ij}_{k}} ] ) \qquad ( 57 )$$

$${V}_{d \sim p ( d )} [ D ( x , {x}^{′} ) ] = \frac{1}{2} ( {E}_{d \sim p ( d )} [ {( {\sum }_{i = 1}^{N} {\prod }_{k = 1}^{{D}_{j}} {σ}_{{ij}_{k}} )}^{2} ] - {( {E}_{d \sim p ( d )} [ {\sum }_{i = 1}^{N} {\prod }_{k = 1}^{{D}_{j}} {σ}_{{ij}_{k}} ] )}^{2} ) \qquad ( 58 )$$

For example, E_{d-p(d)}[D(x,x′)] in Formula (57) corresponds to the mean μ. For example, by increasing E_{d-p(d)}[D(x,x′)] indicating the average in Formula (57), an effect of increasing the average inter-code distance can be obtained. In addition, for example, V_{d-p(d)}[D(x,x′)] in Formula (58) corresponds to the variance σ². For example, by decreasing V_{d-p(d)}[D(x,x′)] in Formula (58) indicating the variance, it is possible to obtain an effect of reducing the variation in the inter-code distance and increasing the minimum inter-code distance. By using such Formulas (57) and (58), the objective function can be transformed as the following Formula (59) by combining Formulas (57) and (58), for example. For example, α, β, and γ in Formula (59) are parameters. In this manner, the transmission device 200 transforms the objective function into the form of the Ising model.

L(σ)=αE_{d-p(d)}[D(x,x′)]+βE_{d-p(d)}[D(x,x′)]²+γV_{d-p(d)}[D(x,x′)] (59)

It is ideally desirable to perform the calculation of the expected value for all possible sequences d. However, since it is difficult to calculate all combinations, sampling is performed according to a certain rule. For example, d is assumed to be a bit sequence having a length M and including “1” s, the number of which is D. There are MCD patterns of these combinations, and all of the combinations may be used or some of these may be selected by sampling. As described above, the objective function written down by the sampling, the removal of mod 2, and the degree reduction becomes a quadratic expression at most regarding the elements of the generator matrix.

### 4-1-3-5. Optimization

Next, a parameter in a quadratic form such as Formula (59) is input to the Ising machine 10. The Ising machine 10 calculates a spin value corresponding to the generator matrix element that increases the inter-code distance. From the obtained spin value, an element of a generator matrix represented by “0” or “1” is calculated.

For example, the transmission device 200 transmits the coefficient (parameter) of the Ising model of Formula (59) derived by the above transformation processing to the Ising machine 10.

Having acquired the coefficient (parameter) of the Ising model of Formula (59) from the transmission device 200, the Ising machine 10 executes calculation and transmits the result to the transmission device 200. The Ising machine 10 transmits the calculated (measured) value of the Ising spin to the transmission device 200. The Ising machine 10 transmits the calculated (measured) value of each element of σ to the transmission device 200.

Subsequently, by converting the acquired value of the Ising spin into the value of the generator matrix using the following Formula (60), the transmission device 200 generates the generator matrix G.

$${ℊ}_{ij} = \frac{1}{2} ( 1 - {σ}_{ij} ) \qquad ( 60 )$$

Formula (60) represents, as an example, a formula for generating an element gᵢⱼ of the i row and j column of the generator matrix G. The element gᵢⱼ is a value obtained by subtracting the corresponding i-j-th Ising spin σᵢⱼ from “1” and multiplying the result by ½. For example, when the value of the Ising spin σᵢⱼ is “−1”, the element gᵢⱼ is “1(=½(1−(−1))”. For example, when the value of the Ising spin σᵢⱼ is “1”, the element gᵢⱼ is “0(=½(1−1))”. In this manner, the transmission device 200 can generate each element of the generator matrix G from the resultant Ising spin. Note that the transmission device 200 generates the generator matrix G by similarly processing other elements other than the i row and j column of the generator matrix G. As described above, transmission device 200 can obtain the optimal message sequence. With the above processing, the transmission device 200 can obtain the elements of the optimized generator matrix.

### 4-2. Configuration of Transmission Device According to Third Embodiment

Next, a configuration of the transmission device 200, which is an example of a conversion device that executes the processing according to the third embodiment, will be described. FIG. 13 is a diagram illustrating a configuration example of a transmission device according to the third embodiment of the present disclosure.

As illustrated in FIG. 13, the transmission device 200 includes a communication unit 210, a storage unit 220, and a control unit 230. Note that, the transmission device 200 may include an input unit (for example, a keyboard, a mouse, etc.) that receives various operations from an administrator or the like of the transmission device 200, and a display unit (for example, a liquid crystal display, etc.) for displaying various types of information.

The communication unit 210 is implemented by a NIC, for example. The communication unit 210 is connected to a predetermined network (not illustrated) in a wired or wireless manner, and transmits and receives information to and from other information processing devices such as the Ising machine 10 and the reception device 100. Furthermore, the communication unit 210 may transmit and receive information to and from a user terminal (not illustrated) used by the user.

The storage unit 220 is implemented by a semiconductor memory element such as RAM or flash memory, or a storage device such as a hard disk or an optical disk, for example. As illustrated in FIG. 13, the storage unit 220 according to the third embodiment includes a data storage unit 221 and a function information storage unit 222.

Although not illustrated, the data storage unit 221 stores various data. The data storage unit 221 stores various data such as data received from another device and decoded data. Although not illustrated, the function information storage unit 222 stores information of various functions. For example, the function information storage unit 222 stores information of various functions used for the conversion processing and the generation processing. For example, the function information storage unit 222 stores information of a function used for processing among the above-described Formulas (1) to (60). Note that the storage unit 220 is not limited to the above, and may store various types of information depending on the purpose.

The control unit 230 is implemented by execution of programs stored in the transmission device 200 (for example, a conversion processing program according to the present disclosure) by the CPU, MPU, or the like, using RAM or the like as a working area. Furthermore, the control unit 230 is implemented by an integrated circuit such as ASIC or FPGA.

As illustrated in FIG. 13, the control unit 230 includes a reception unit 231, a first arithmetic unit 232, a second arithmetic unit 233, a third arithmetic unit 234, a generation unit 235, and a transmission unit 236, and implements or executes a function and an action of information processing described below. The internal configuration of the control unit 230 is not limited to the configuration illustrated in FIG. 13, and may be another configuration as long as it is a configuration that performs information processing described below. Furthermore, the connection relationship of the processing units included in the control unit 230 is not limited to the connection relationship illustrated in FIG. 13, and may be a different connection relationship.

The reception unit 231 receives various types of information. The reception unit 231 receives various types of information from an external information processing device. The reception unit 231 receives various types of information from the Ising machine 10.

The reception unit 231 acquires various types of information from the storage unit 220. The reception unit 231 acquires various types of information from the data storage unit 221 and the function information storage unit 222.

The first arithmetic unit 232 executes various types of arithmetic processing. The first arithmetic unit 232 executes processing related to conversion of the objective function into the form of the Ising model. The first arithmetic unit 232 executes the first transformation. The first arithmetic unit 232 executes arithmetic processing by using information stored in the data storage unit 221 or the function information storage unit 222. The first arithmetic unit 232 executes the first transformation using the information of the function stored in the function information storage unit 222. The first arithmetic unit 232 executes the first transformation on the information received by the reception unit 231.

The first arithmetic unit 232 removes the modulo 2 operation from the objective function by using the first transformation. By using the first transformation, the first arithmetic unit 232 converts the form of the objective function from Formula (52) into Formula (54), thereby removing the mod 2 operation.

The second arithmetic unit 233 executes various types of arithmetic processing. The second arithmetic unit 233 executes processing related to conversion of the objective function into the form of the Ising model. The second arithmetic unit 233 executes the second transformation. The second arithmetic unit 233 executes arithmetic processing using the information stored in the data storage unit 221 or the function information storage unit 222. The second arithmetic unit 233 executes the second transformation using the information of the function stored in the function information storage unit 222. The second arithmetic unit 233 executes the second transformation on the objective function that has undergone the first transformation by the first arithmetic unit 232.

By using the second transformation, the second arithmetic unit 233 replaces the first variable corresponding to the target included in the objective function with the second variable corresponding to the Ising spin. The second arithmetic unit 233 executes second transformation of replacing the first variable corresponding to the target included in the objective function with the second variable corresponding to the Ising spin. The second arithmetic unit 233 converts the form of the objective function from Formula (54) into Formula (55) by using the second transformation, and replaces the first variable corresponding to the target with the second variable corresponding to the Ising spin.

The third arithmetic unit 234 executes various types of arithmetic processing. The third arithmetic unit 234 executes processing related to conversion of the objective function into the form of the Ising model. The third arithmetic unit 234 executes the third transformation. The third arithmetic unit 234 executes arithmetic processing using the information stored in the data storage unit 221 or the function information storage unit 222. The third arithmetic unit 234 executes the third transformation using the information of the function stored in the function information storage unit 222. The third arithmetic unit 234 executes the third transformation on the objective function that has undergone the second transformation by the second arithmetic unit 233.

The third arithmetic unit 234 reduces the degree of the second variable by using the third transformation. The third arithmetic unit 234 executes a third transformation of adding a constraint term to the objective function according to the reduction of the degree of the second variable. The third arithmetic unit 234 converts the objective function into the form of the Ising model by using the third transformation that reduces the degree of the second variable to the second degree.

In the example of FIG. 12, the third arithmetic unit 234 reduces the degree of the second variable “σ” by using the third transformation. The third arithmetic unit 234 transforms the form of the objective function from Formula (52) to Formula (59).

The generation unit 235 generates various types of information. The generation unit 235 generates various types of information based on information from an external information processing device or information stored in the storage unit 220. The generation unit 235 generates various types of information based on information from other information processing devices such as the Ising machine 10 and the transmission device 200. The generation unit 235 generates various types of information based on the information stored in the data storage unit 221 or the function information storage unit 222.

The generation unit 235 generates various types of information based on the various types of information acquired by the reception unit 231. The generation unit 235 executes decoding processing using the calculation result of the Ising machine 10 acquired from the Ising machine 10, and generates decoded information.

The generation unit 235 generates information in which the codeword received by the reception unit 231 has been decoded, by using a value of an Ising spin calculated based on an objective function converted into a form of an Ising model and using a function that converts the Ising spin into a message, the objective function having been converted into the form of the Ising model by removing a modulo 2 operation from a target objective function related to decoding in the coding, replacing the first variable corresponding to the target included in the objective function with a second variable corresponding to the Ising spin, and reducing the degree of the second variable.

For example, the generation unit 235 combines Formulas (57) and (58) to transform the objective function into Formula (59) in the form of an Ising model.

The transmission unit 236 provides various types of information to an external information processing device. The transmission unit 236 transmits various types of information to an external information processing device. For example, the transmission unit 236 transmits various types of information to other information processing devices such as the Ising machine 10 and the transmission device 200. The transmission unit 236 provides the information stored in the storage unit 220. The transmission unit 236 transmits the information stored in the storage unit 220.

The transmission unit 236 provides various types of information based on information from other information processing devices such as the Ising machine 10 and the reception device 100. The transmission unit 236 provides various types of information based on the information stored in the storage unit 220. The transmission unit 236 provides various types of information based on the information stored in the data storage unit 221 or the function information storage unit 222. The transmission unit 236 transmits the codeword generated by the generation unit 235 to the reception device 100.

The acquisition unit 141 of the Ising machine 10 according to the third embodiment receives various types of information from other information processing devices such as the reception device 100 and the transmission device 200. For example, the acquisition unit 141 receives the coefficient (parameter) of the Ising model of the above Formula (59) from the transmission device 200.

The transmission unit 143 of the Ising machine 10 according to the third embodiment transmits various types of information to other information processing devices such as the reception device 100 and the transmission device 200. The transmission unit 143 transmits various types of information based on information from another information processing device such as the reception device 100 and the transmission device 200. The transmission unit 143 transmits the measurement result of the quantum device unit 13 by the calculation unit 142 to another information processing device such as the reception device 100 or the transmission device 200. For example, the transmission unit 143 transmits the value of the Ising spin calculated (measured) using the parameter received from the transmission device 200 to the reception device 100. The transmission unit 143 transmits the calculated (measured) value of each element of σ to the transmission device 200.

### 4-3. Example of Configuration of Communication System

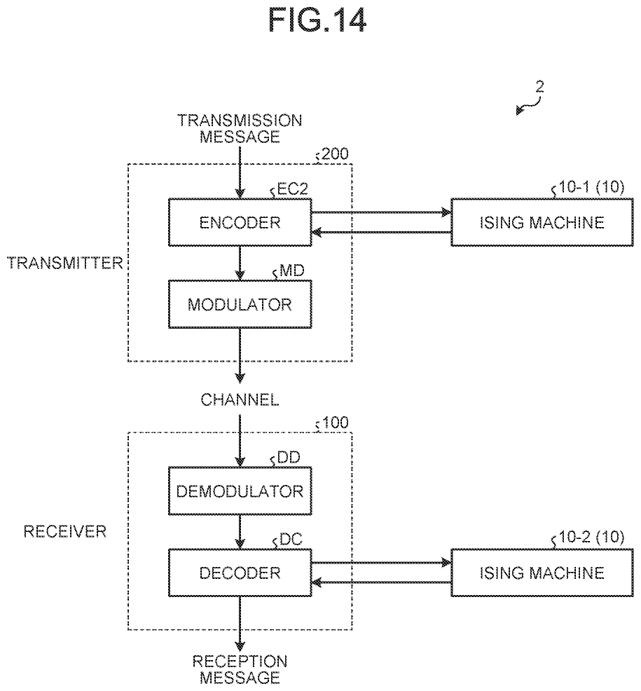

Here, a configuration of the communication system illustrated in FIG. 14 will be described. FIG. 14 is a diagram illustrating an example of a configuration of a communication system. The configuration of the communication system 2 illustrated in FIG. 14 is different from the communication system 1 of FIG. 6 in that an Ising machine 10 is provided on the transmission side. Hereinafter, description of the points similar to FIG. 6 will be omitted as appropriate.

In the communication system 2 illustrated in FIG. 14, the transmission device 200 which is a transmission-side device (transmitter) has a configuration including an encoder EC2 and a modulator MD. As described above, (the encoder EC2 of) the transmission device 200 causes the Ising machine 10 to perform calculation to acquire the value of the Ising spin, and using the acquired value of the Ising spin to obtain a generator matrix, and using the generator matrix to generate a codeword from the message. The transmission device 200 transmits information (signal) obtained by converting a transmission message using the encoder EC2 or the modulator MD to the reception device 100 which is a reception-side device (receiver) via a channel.

### 4-3-1. Procedure of Encoding Processing Related to Communication System

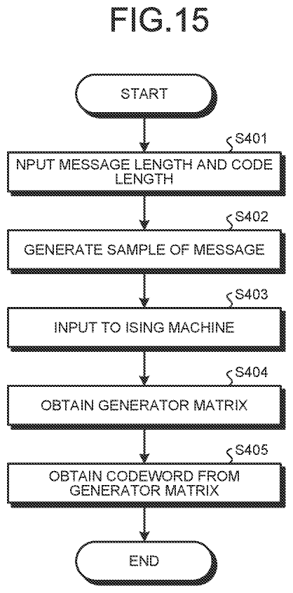

Next, a flow of decoding processing related to the communication system will be described with reference to FIG. 15. FIG. 15 is a flowchart illustrating a procedure of decoding processing performed by the communication system.

As illustrated in FIG. 15, the transmission device 200 inputs a message length and a code length (step S401). Subsequently, the transmission device 200 generates a sample of the message (step S402). The sample of the message is used when the calculation of the parameter of the Ising model is omitted. When the parameters of the Ising model can be easily and analytically calculated, this processing is unnecessary.

Next, the transmission device 200 performs input to the Ising machine 10 (step S403). For example, the transmission device 200 inputs parameters and the like to the Ising machine 10. The Ising machine 10 receives input of an objective function for optimizing a generator matrix and parameters of energy in a quadratic form in consideration of a constraint term for degree reduction.

The transmission device 200 obtains a generator matrix (step S404). The transmission device 200 then obtains a codeword from the generator matrix (step S405). With annealing processing in the Ising machine 10, one optimal matrix element is obtained. Since this element is obtained with a value of “−1” or “1” from the Ising machine, it is converted into values of “0” and “1” to be an element of the generator matrix. Finally, a codeword is obtained from the generator matrix thus obtained.

### 5. OTHER CONFIGURATION EXAMPLES, ETC.

The processing according to the above-described embodiments and modifications may be performed in various different forms (modifications) other than the above-described embodiments and modifications.

### 5-1. Other Configuration Examples

Although the above is an exemplary case where the reception devices 100, 100A and the transmission device 200 are separated from the Ising machine 10, the reception devices 100, 100A and the Ising machine 10 may be integrated to each other, or the transmission device 200 and the Ising machine 10 may be integrated with each other. For example, when the Ising machine 10 is implemented by a digital circuit without using superconductivity, the Ising machine 10 may be arranged on the edge side. For example, in a case where the calculation using the Ising model is performed on the edge side, the reception devices 100, 100A and the Ising machine 10 may be integrated, or the reception devices 100, 100A and the Ising machine 10 may be integrated.

### 5-2. Comparison with Known Technique

Here, a comparison between the present disclosure and a known technique will be briefly described.

### 5-2-1. Speed Up Searching Coding Method

First, speeding up the search of the coding method will be described.

In a known technique, a search for a good coding method has been performed through the following procedure. In this case, the check matrix is randomly created under the constraint that the matrix is sparse. In addition, correction is made so as to avoid the loop of the Tanner graph on the check matrix. Furthermore, a generator matrix is constructed from the check matrix. In addition, in a known technique, the communication state is simulated and the accuracy is evaluated by the following procedure.

First, a message is randomly generated. Using the generator matrix, a transmission bit string is generated. Subsequently, noise (specifically, white Gaussian noise) is added to the transmission bit string to generate a reception bit string. From the received bit string, a message is estimated. An error rate between the estimated message and the original message is calculated. Calculation is repeated to obtain a statistical error rate. Subsequently, the error rate with respect to the Shannon channel capacity is evaluated. When the evaluated rate is far from the Shannon channel capacity, the above procedure is repeated to search for the coding method again.

In contrast, in the present disclosure, encoding can be easily implemented as follows. For example, in the third embodiment, encoding can be easily implemented as follows.

First, a quadratic form to be satisfied by the generator matrix is calculated. A parameter in a quadratic form is input to the Ising machine. The elements of the generator matrix are obtained from the Ising machine.

### 5-2-2. Real Time Code Generation

In the known technique, implementation of an accurate coding method takes time, and thus, the coding method cannot be changed so often.

In contrast, the coding method in the present disclosure can be changed relatively frequently. For example, it is conceivable, by using this, that a new coding method is generated at the same time while a sender transmits a message, and the message is utilized to share the new coding method with the recipient. By sharing the new coding method in the middle in this manner, the coding method can be concealed, leading to achievement of communication with higher security.

### 5-3. Application Examples

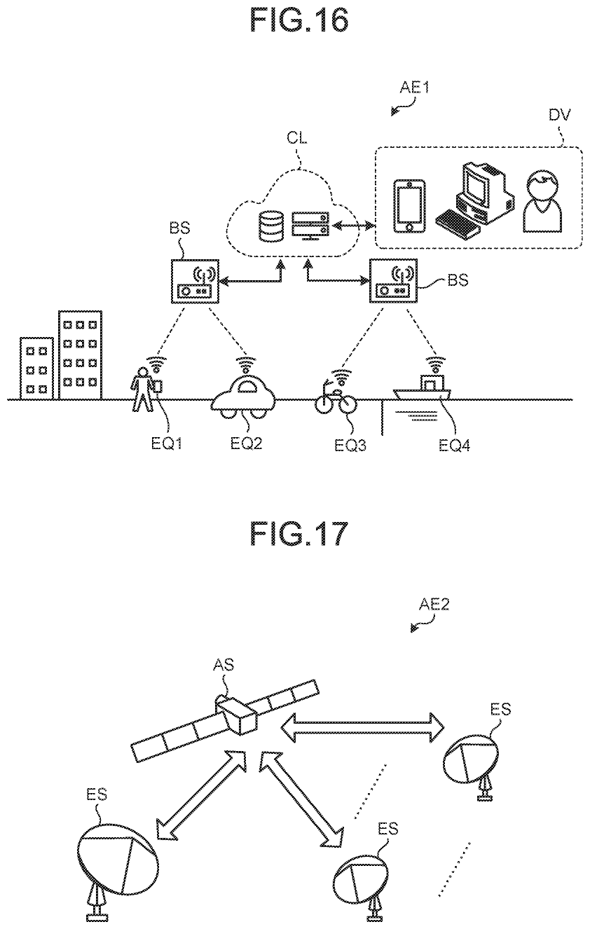

Furthermore, the communication systems 1, 2 described above may be applied to various systems. An example of this point will be briefly described with reference to FIGS. 16 and 17.

### 5-3-1. Application Example #1 (Iot)

FIG. 16 is a conceptual diagram illustrating an example of application of a communication system. An application system AE1 illustrated in FIG. 16 illustrates an example of an Internet of Things (IoT) network service using a predetermined radio communication standard.

The application system AE1 in FIG. 16 includes a user device DV such as a mobile terminal, various IoT sensors EQ1, EQ2, EQ3, and EQ4 (referred to as “IoT sensor EQ”), a relay base station BS, and a cloud CL. For example, when the IoT sensor EQ and the relay base station BS communicate with each other, the technique of encoding or decoding using the Ising model described above is used.

### 5-3-2. Application Example #2 (Satellite Communication)

FIG. 17 is a conceptual diagram illustrating an example of application of a communication system. An application system AE2 illustrated in FIG. 16 illustrates an example of satellite communication.

The application system AE2 of FIG. 17 includes a communication satellite AS, a base station ES which is a transmission base station or a reception base station (tuner). For example, when the communication satellite AS and the base station ES communicate with each other, a technique of encoding or decoding using the Ising model described above is used.

### 5-4. Method of Generating Information Used for Processing of Program, Parameter, and the Like

A method of generating the above-described conversion processing, parameters, and the like may be provided. Furthermore, a method of generating a program used when the above-described Ising machine 10 executes calculation may be provided.

### 5-5. Others

Furthermore, among each processing described in the above embodiments, all or a part of the processing described as being performed automatically can be manually performed, or the processing described as being performed manually can be performed automatically by a known method. In addition, the processing procedures, specific names, and information including various data and parameters illustrated in the above specifications or drawings can be changed in any manner unless otherwise specified. For example, various types of information illustrated in each of the drawings are not limited to the information illustrated.

In addition, each of the components of each of the illustrated devices is provided as a functional and conceptional illustration and thus does not necessarily have to be physically configured as illustrated. That is, the specific form of distribution/integration of each of devices is not limited to those illustrated in the drawings, and all or a part thereof may be functionally or physically distributed or integrated into arbitrary units according to various loads and use conditions.

Furthermore, the above-described embodiments and modifications can be appropriately combined within a range implementable without contradiction of processing.

The effects described in the present specification are merely examples, and thus, there may be other effects, not limited to the exemplified effects.

### 6. EFFECTS ACCORDING TO PRESENT DISCLOSURE

As described above, the conversion method according to the present disclosure is a conversion method of converting an objective function of combinatorial optimization related to encoding and decoding into a form of an Ising model, in which the objective function is converted into the form of the Ising model by removing a modulo 2 operation from the objective function by using the first transformation, replacing a first variable to be optimized included in the objective function with a second variable corresponding to an Ising spin by using the second transformation, and reducing the degree related to the second variable of the objective function by using the third transformation.

In this manner, the conversion method transforms the objective function of the combinatorial optimization related to encoding and decoding into the form of the Ising model by using the first to third transformations. With this operation, the conversion method can apply the Ising model to the processing related to encoding and decoding. That is, a computer executing the conversion method can apply the Ising model to the processing related to encoding and decoding.

In addition, the conversion method according to the present disclosure converts the objective function into the form of the Ising model by using the third transformation in which the second variable is added according to the reduction of the degree related to the second variable of the objective function, and a constraint term is added to the objective function related to the added second variable. This enables the conversion method to generate the objective function in the form of the Ising model to which the constraint term has been added according to the reduction of the degree of the second variable, making it possible to apply the Ising model to the processing related to the coding. That is, the computer that executes the conversion method can apply the Ising model to the processing related to encoding.

In addition, the conversion method according to the present disclosure converts the objective function into the form of the Ising model by using the third transformation that reduces the degree of the second variable of the objective function to the second degree or less. With this operation, the conversion method can solve a problem related to encoding and decoding with the Ising model. That is, a computer executing the conversion method can apply the Ising model to the processing related to encoding and decoding.

In addition, the conversion method according to the present disclosure converts a target objective function related to channel encoding and decoding into a form of an Ising model. With this operation, the conversion method can apply the Ising model to processing related to channel encoding and decoding. That is, a computer executing the conversion method can apply the Ising model to the processing related to encoding and decoding.

In addition, a conversion method according to the present disclosure converts an objective function related to a linear code into the form of an Ising model. This enables the conversion method to solve a problem related to the linear code by using the Ising model. That is, the computer that executes the conversion method can apply the Ising model to the processing related to encoding.

Furthermore, a conversion method according to the present disclosure is a conversion method of converting an objective function of combinatorial optimization related to decoding in the coding into a form of an Ising model, in which the objective function is converted into the form of the Ising model by using the second transformation of replacing a first variable to be optimized included in the objective function with a second variable corresponding to an Ising spin. With this operation, the conversion method can make it possible to use the Ising model for decoding the encoded information. That is, the computer that executes the conversion method can apply the Ising model to the processing related to encoding.

In addition, the conversion method according to the present disclosure converts an objective function used for decoding information transferred between communication devices into a form of an Ising model. This enables the conversion method to use the Ising model for decoding information transferred between communication devices. That is, the computer that executes the conversion method can apply the Ising model to the processing related to encoding.

Furthermore, a conversion method according to the present disclosure converts an objective function used for decoding information received by a communication device from another communication device into a form of the Ising model. This enables the conversion method to use the Ising model to decode the received information. That is, the computer that executes the conversion method can apply the Ising model to the processing related to encoding.

In addition, in the conversion method according to the present disclosure, the first variable is a variable constituting a message to be restored. This enables the conversion method to use the Ising model for decoding information. That is, the computer that executes the conversion method can apply the Ising model to the processing related to encoding.

Furthermore, in the conversion method according to the present disclosure, the first variable is a variable constituting a codeword to be decoded. This enables the conversion method to use the Ising model for decoding information. That is, the computer that executes the conversion method can apply the Ising model to the processing related to encoding.

Furthermore, in the conversion method according to the present disclosure, the objective function for combinatorial optimization is an objective function for maximum likelihood decoding regarding the first variable. This enables the conversion method to use the Ising model for maximum likelihood decoding. That is, the computer that executes the conversion method can apply the Ising model to the processing related to encoding.

Furthermore, in the conversion method according to the present disclosure, the objective function of combinatorial optimization is an objective function of maximum likelihood decoding using a generator matrix. This enables the conversion method to convert the objective function of the maximum likelihood decoding using the generator matrix in the encoding into the form of the Ising model, making it possible to apply the Ising model to the processing related to encoding. That is, the computer that executes the conversion method can apply the Ising model to the processing related to encoding.

In addition, in the conversion method according to the present disclosure, the objective function of combinatorial optimization is an objective function of maximum likelihood decoding in which a constraint of parity check related to a codeword is a constraint term. This enables the conversion method to convert the objective function of the maximum likelihood decoding having the constraint of the parity check as the constraint term into the form of the Ising model, making it possible to apply the Ising model to the processing related to encoding. That is, the computer that executes the conversion method can apply the Ising model to the processing related to encoding.

Furthermore, a conversion method according to the present disclosure is a conversion method of converting an objective function of combinatorial optimization used for encoding into a form of an Ising model, in which the objective function is converted into the form of the Ising model by using the second transformation of replacing a first variable to be optimized included in the objective function with a second variable corresponding to an Ising spin. This enables the conversion method to use the Ising model for processing related to encoding. That is, the computer that executes the conversion method can apply the Ising model to the processing related to encoding.

Furthermore, the conversion method according to the present disclosure converts an objective function used for encoding information transmitted from a communication device to another communication device into a form of an Ising model. This enables the conversion method to use the Ising model for encoding information to be transmitted. That is, the computer that executes the conversion method can apply the Ising model to the processing related to encoding.

Furthermore, in the conversion method according to the present disclosure, the first variable is an element constituting the generator matrix used for encoding. This enables the conversion method to use the Ising model to generate a generator matrix. That is, the computer that executes the conversion method can apply the Ising model to the processing related to encoding.

As described above, a conversion device (reception devices 100, 100A and the transmission device 200 in the embodiment) according to the present disclosure is a device of converting an objective function of optimization related to encoding and decoding into a form of an Ising model, the conversion of the objective function into the form of the Ising model is performed by the conversion device, and the conversion device includes: a first arithmetic unit (first arithmetic units 132, 132A, and 232 in the embodiment) that removes a modulo 2 operation from the objective function by using first transformation; a second arithmetic unit (second arithmetic units 133, 133A, and 233 in the embodiment) that replaces a first variable to be optimized included in the objective function with a second variable corresponding to an Ising spin by using second transformation; and a third arithmetic unit (third arithmetic units 134, 134A, and 234 in the embodiment) that reduces the degree of a second variable related to the objective function by using third transformation.

In this manner, the conversion device transforms the target objective function related to encoding by using the first to third transformations to convert the target objective function into the form of the Ising model. With this operation, the conversion device can apply the Ising model to the processing related to encoding.

As described above, the reception device (reception device 100 and 100A in the embodiment) according to the present disclosure includes: a reception unit (reception unit 131 in the embodiment) that receives a codeword including a message encoded by encoding from a transmission device; and a generation unit (generation units 135 and 135A in the embodiment) that generates information in which the codeword received by the reception unit has been decoded, the generation of the information being performed by using a value of an Ising spin and by a function that converts the Ising spin into the message, the value of the Ising spin having been calculated based on an objective function of combinatorial optimization related to decoding in the coding, the objective function having been converted into a form of an Ising model by removing a modulo 2 operation from the objective function, replacing a first variable to be optimized included in the objective function with a second variable corresponding to the Ising spin, and reducing a degree related to the second variable of the objective function.

In this manner, the reception device generates information in which the received codeword has been decoded by using the value of the Ising spin calculated based on the objective function converted into the form of the Ising model by the first to third transformations and the function that converts the Ising spin into the message. With this operation, the reception device can appropriately decode the received information by using the Ising model. Therefore, the reception device can apply the Ising model to the processing related to the encoding.

As described above, the transmission device (transmission device 200 in the embodiment) according to the present disclosure includes: a generation unit (generation unit 235) that generates a codeword including an encoded message, the generation of the codeword being performed by a generator matrix, the generator matrix being generated by a value of an Ising spin and a function that converts the Ising spin into the generator matrix, the value of the Ising spin having been calculated based on an objective function of combinatorial optimization to be used for encoding, the objective function having been converted into a form of an Ising model by removing a modulo 2 operation from the objective function, replacing a first variable to be optimized included in the objective function with a second variable corresponding to the Ising spin, and reducing a degree related to the second variable of the objective function; and a transmission unit (transmission unit 236 in the embodiment) that transmits the codeword generated by the generation unit to a reception device.

In this manner, the transmission device generates the codeword in which the message is encoded by the generator matrix generated using the value of the Ising spin calculated based on the objective function converted into the form of the Ising model by the first to third transformations and using the function that converts the Ising spin into the generator matrix. This enables the transmission device to appropriately encode the transmitted information by using the Ising model. Therefore, the transmission device can apply the Ising model to the processing related to the encoding.

### 7. HARDWARE CONFIGURATION

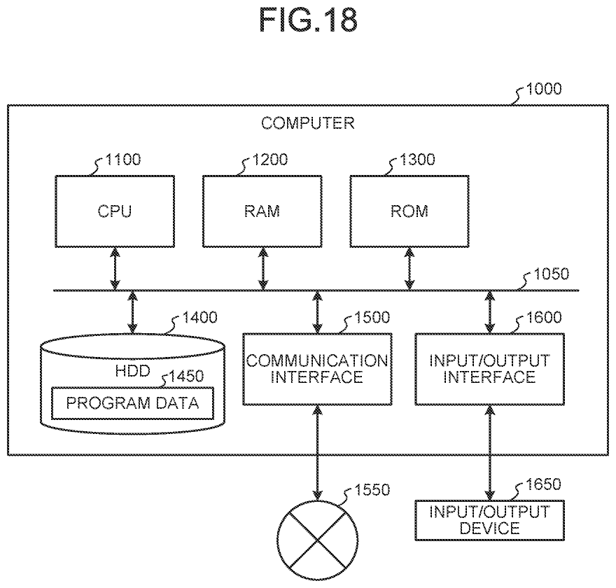

The information devices such as the reception devices 100, 100A and the transmission devices 50, 200 according to the embodiments and the modifications described above are implemented by a computer 1000 having a configuration as illustrated in FIG. 18, for example. FIG. 18 is a hardware configuration diagram illustrating an example of the computer 1000 that implements the functions of the information processing devices such as the reception devices 100 and 100A and the transmission devices 50 and 200. Hereinafter, the reception device 100 according to the first embodiment will be described as an example. The computer 1000 includes a CPU 1100, RAM 1200, read only memory (ROM) 1300, a hard disk drive (HDD) 1400, a communication interface 1500, and an input/output interface 1600. Individual units of the computer 1000 are interconnected by a bus 1050.

The CPU 1100 operates based on a program stored in the ROM 1300 or the HDD 1400 so as to control each unit. For example, the CPU 1100 develops the program stored in the ROM 1300 or the HDD 1400 into the RAM 1200 and executes processing corresponding to various programs.

The ROM 1300 stores a boot program such as a basic input output system (BIOS) executed by the CPU 1100 when the computer 1000 starts up, a program dependent on hardware of the computer 1000, or the like.

The HDD 1400 is a non-transitory computer-readable recording medium that records a program executed by the CPU 1100, data used by the program, or the like. Specifically, the HDD 1400 is a recording medium that records an information processing program such as a conversion processing program, and the like according to the present disclosure, which is an example of program data 1450.

The communication interface 1500 is an interface for connecting the computer 1000 to an external network 1550 (for example, the Internet). For example, the CPU 1100 receives data from other devices or transmits data generated by the CPU 1100 to other devices via the communication interface 1500.

The input/output interface 1600 is an interface for connecting between an input/output device 1650 and the computer 1000. For example, the CPU 1100 receives data from an input device such as a keyboard or a mouse via the input/output interface 1600. In addition, the CPU 1100 transmits data to an output device such as a display, a speaker, or a printer via the input/output interface 1600. Furthermore, the input/output interface 1600 may function as a media interface for reading a program or the like recorded on predetermined recording medium (or simply medium). Examples of the media include optical recording media such as a digital versatile disc (DVD) or a phase change rewritable disk (PD), a magneto-optical recording medium such as a magneto-optical disk (MO), a tape medium, a magnetic recording medium, and semiconductor memory.

For example, when the computer 1000 functions as the reception device 100 according to the first embodiment, the CPU 1100 of the computer 1000 executes the information processing program such as a conversion processing program loaded on the RAM 1200 so as to implement the functions of the control unit 130 and the like. Furthermore, the HDD 1400 stores the information processing program such as the conversion processing program according to the present disclosure or data in the storage unit 120. While the CPU 1100 executes program data 1450 read from the HDD 1400, the CPU 1100 may acquire these programs from another device via the external network 1550, as another example.

Note that the present technique can also have the following configurations.

(1)

A conversion method of converting an objective function of combinatorial optimization related to encoding and decoding into a form of an Ising model, the conversion of the objective function into the form of the Ising model being performed by using the conversion method, the conversion method comprising:

removing a modulo 2 operation from the objective function by using first transformation;

replacing a first variable to be optimized included in the objective function with a second variable corresponding to an Ising spin by using second transformation; and

reducing a degree of the second variable related to the objective function by using third transformation.

(2)

The conversion method according to (1), wherein the objective function is converted into the form of the Ising model by using the third transformation of adding the second variable according to the reduction of the degree of the second variable, and adding a constraint term related to the second variable added to the objective function.

(3)

The conversion method according to (1) or (2), wherein the objective function is converted into the form of the Ising model by using the third transformation of reducing the degree of the second variable of the objective function to a second degree or less.

(4)

The conversion method according to any one of (1) to (3), wherein the objective function related to channel coding is converted into the form of the Ising model.

(5)

The conversion method according to any one of (1) to (4), wherein the objective function related to a linear code is converted into the form of the Ising model.

(6)

The conversion method according to any one of (1) to (5), the conversion method being adapted to convert an objective function of the combinatorial optimization related to decoding in coding into the form of the Ising model,

wherein the objective function is converted into the form of the Ising model by using the second transformation of replacing the first variable to be optimized included in the objective function with the second variable corresponding to the Ising spin.

(7)

The conversion method according to (6), wherein the objective function used for decoding information transferred between communication devices is converted into the form of the Ising model.

(8)

The conversion method according to (7), wherein the objective function used for decoding information received by a communication device from another communication device is converted into the form of the Ising model.

(9)

The conversion method according to any one of (6) to (8), wherein the first variable is a variable constituting a message to be restored.

(10)

The conversion method according to any one of (6) to (8), wherein the first variable is a variable constituting a codeword to be decoded.

(11)

The conversion method according to any one of (6) to (10), wherein the objective function of the combinatorial optimization is an objective function of maximum likelihood decoding related to the first variable.

(12)

The conversion method according to any one of (6) to (11), wherein the objective function of the combinatorial optimization is an objective function of maximum likelihood decoding using a generator matrix.

(13)

The conversion method according to any one of (6) to (11), wherein the objective function of the combinatorial optimization is an objective function of maximum likelihood decoding in which a constraint of parity check related to a codeword is a constraint term.

(14)

The conversion method according to any one of (1) to (5), the conversion method adapted to convert an objective function of the combinatorial optimization used for encoding into the form of the Ising model, wherein the objective function is converted into the form of the Ising model by the second transformation of replacing the first variable to be optimized included in the objective function with the second variable corresponding to the Ising spin.

(15)

The conversion method according to (14), wherein the objective function used for encoding information transmitted from a communication device to another communication device is converted into the form of the Ising model.

(16)

The conversion method according to (14) or (15), wherein the first variable is an element constituting a generator matrix used for encoding.

(17)

A conversion device that converts an objective function of optimization related to encoding and decoding into a form of an Ising model, the conversion of the objective function into the form of the Ising model being performed by using the conversion device, the conversion device comprising:

a first arithmetic unit that removes a modulo 2 operation from the objective function by using first transformation;

a second arithmetic unit that replaces a first variable to be optimized included in the objective function with a second variable corresponding to an Ising spin by using second transformation; and

a third arithmetic unit that reduces a degree of the second variable related to the objective function by using third transformation.

(18)

A reception device comprising:

a reception unit that receives a codeword including a message encoded by encoding, from a transmission device; and

a generation unit that generates information in which the codeword received by the reception unit has been decoded, the generation of the information being performed by using a value of an Ising spin and by a function that converts the Ising spin into the message, the value of the Ising spin having been calculated based on an objective function of combinatorial optimization related to decoding in the encoding, the objective function having been converted into a form of an Ising model by removing a modulo 2 operation from the objective function, replacing a first variable to be optimized included in the objective function with a second variable corresponding to the Ising spin, and reducing a degree related to the second variable of the objective function.

(19)

A transmission device comprising:

a generation unit that generates a codeword including an encoded message, the generation of the codeword being performed by a generator matrix, the generator matrix having been generated by a value of an Ising spin and a function that converts the Ising spin into the generator matrix, the value of the Ising spin having been calculated based on an objective function of combinatorial optimization to be used for encoding, the objective function having been converted into a form of an Ising model by removing a modulo 2 operation from the objective function, replacing a first variable to be optimized included in the objective function with a second variable corresponding to the Ising spin, and reducing a degree related to the second variable of the objective function; and

a transmission unit that transmits the codeword generated by the generation unit to a reception device.

### REFERENCE SIGNS LIST

1, 2 COMMUNICATION SYSTEM
100, 100A RECEPTION DEVICE
110 COMMUNICATION UNIT
120, 120A STORAGE UNIT
121 DATA STORAGE UNIT
122, 122A FUNCTION INFORMATION STORAGE UNIT
130, 130A CONTROL UNIT
131 RECEPTION UNIT
132, 132A FIRST ARITHMETIC UNIT
133, 133A SECOND ARITHMETIC UNIT
134, 134A THIRD ARITHMETIC UNIT
135, 135A GENERATION UNIT
136 TRANSMISSION UNIT
10 ISING MACHINE
11 COMMUNICATION UNIT
12 STORAGE UNIT
13 QUANTUM DEVICE UNIT
14 CONTROL UNIT
141 ACQUISITION UNIT
142 CALCULATION UNIT
143 TRANSMISSION UNIT
200, 50 TRANSMISSION DEVICE
210 COMMUNICATION UNIT
220 STORAGE UNIT
221 DATA STORAGE UNIT
222 FUNCTION INFORMATION STORAGE UNIT
230 CONTROL UNIT
231 RECEPTION UNIT
232 FIRST ARITHMETIC UNIT
233 SECOND ARITHMETIC UNIT
234 THIRD ARITHMETIC UNIT
235 GENERATION UNIT
236 TRANSMISSION UNIT

1. A conversion method of converting an objective function of combinatorial optimization related to encoding and decoding into a form of an Ising model, the conversion of the objective function into the form of the Ising model being performed by using the conversion method, the conversion method comprising:
removing a modulo 2 operation from the objective function by using first transformation;
replacing a first variable to be optimized included in the objective function with a second variable corresponding to an Ising spin by using second transformation; and
reducing a degree of the second variable related to the objective function by using third transformation.

2. The conversion method according to claim 1, wherein the objective function is converted into the form of the Ising model by using the third transformation of adding the second variable according to the reduction of the degree of the second variable, and adding a constraint term related to the second variable added to the objective function.

3. The conversion method according to claim 1, wherein the objective function is converted into the form of the Ising model by using the third transformation of reducing the degree of the second variable of the objective function to a second degree or less.

4. The conversion method according to claim 1, wherein the objective function related to channel coding is converted into the form of the Ising model.

5. The conversion method according to claim 1, wherein the objective function related to a linear code is converted into the form of the Ising model.

6. The conversion method according to claim 1, the conversion method being adapted to convert an objective function of the combinatorial optimization related to decoding in coding into the form of the Ising model,
wherein the objective function is converted into the form of the Ising model by using the second transformation of replacing the first variable to be optimized included in the objective function with the second variable corresponding to the Ising spin.

7. The conversion method according to claim 6, wherein the objective function used for decoding information transferred between communication devices is converted into the form of the Ising model.

8. The conversion method according to claim 7, wherein the objective function used for decoding information received by a communication device from another communication device is converted into the form of the Ising model.

9. The conversion method according to claim 6, wherein the first variable is a variable constituting a message to be restored.

10. The conversion method according to claim 6, wherein the first variable is a variable constituting a codeword to be decoded.

11. The conversion method according to claim 6, wherein the objective function of the combinatorial optimization is an objective function of maximum likelihood decoding related to the first variable.

12. The conversion method according to claim 6, wherein the objective function of the combinatorial optimization is an objective function of maximum likelihood decoding using a generator matrix.

13. The conversion method according to claim 6, wherein the objective function of the combinatorial optimization is an objective function of maximum likelihood decoding in which a constraint of parity check related to a codeword is a constraint term.

14. The conversion method according to claim 1, the conversion method adapted to convert an objective function of the combinatorial optimization used for encoding into the form of the Ising model,
wherein the objective function is converted into the form of the Ising model by the second transformation of replacing the first variable to be optimized included in the objective function with the second variable corresponding to the Ising spin.

15. The conversion method according to claim 14, wherein the objective function used for encoding information transmitted from a communication device to another communication device is converted into the form of the Ising model.

16. The conversion method according to claim 14, wherein the first variable is an element constituting a generator matrix used for encoding.

17. A conversion device that converts an objective function of optimization related to encoding and decoding into a form of an Ising model, the conversion of the objective function into the form of the Ising model being performed by using the conversion device, the conversion device comprising:
a first arithmetic unit that removes a modulo 2 operation from the objective function by using first transformation;
a second arithmetic unit that replaces a first variable to be optimized included in the objective function with a second variable corresponding to an Ising spin by using second transformation; and
a third arithmetic unit that reduces a degree of the second variable related to the objective function by using third transformation.

18. A reception device comprising:
a reception unit that receives a codeword including a message encoded by encoding, from a transmission device; and
a generation unit that generates information in which the codeword received by the reception unit has been decoded, the generation of the information being performed by using a value of an Ising spin and by a function that converts the Ising spin into the message, the value of the Ising spin having been calculated based on an objective function of combinatorial optimization related to decoding in the encoding, the objective function having been converted into a form of an Ising model by removing a modulo 2 operation from the objective function, replacing a first variable to be optimized included in the objective function with a second variable corresponding to the Ising spin, and reducing a degree related to the second variable of the objective function.

19. A transmission device comprising:
a generation unit that generates a codeword including an encoded message, the generation of the codeword being performed by a generator matrix, the generator matrix having been generated by a value of an Ising spin and a function that converts the Ising spin into the generator matrix, the value of the Ising spin having been calculated based on an objective function of combinatorial optimization to be used for encoding, the objective function having been converted into a form of an Ising model by removing a modulo 2 operation from the objective function, replacing a first variable to be optimized included in the objective function with a second variable corresponding to the Ising spin, and reducing a degree related to the second variable of the objective function; and
a transmission unit that transmits the codeword generated by the generation unit to a reception device.
